(19) United States
(12) Patent Application Publication
(10) Pub. No.: US 2025/0365911 A1
(43) Pub. Date: Nov. 27, 2025

(54) SEMICONDUCTOR STRUCTURE AND MANUFACTURING METHOD THEREOF

(71) Applicants: TAIWAN SEMICONDUCTOR MANUFACTURING COMPANY, LTD., Hsinchu (TW); NATIONAL TAIWAN UNIVERSITY, TAIPEI (TW)

(72) Inventors: Tao CHOU, New Taipei City (TW); Tzu Yun LIU, New Taipei City (TW); Jih-Chao CHIU, New Taipei City (TW); Chee-Wee LIU, Taipei City (TW)

(73) Assignees: TAIWAN SEMICONDUCTOR MANUFACTURING COMPANY, LTD., Hsinchu (TW); NATIONAL TAIWAN UNIVERSITY, TAIPEI (TW)

(21) Appl. No.: 18/892,050

(22) Filed: Sep. 20, 2024

Related U.S. Application Data
(60) Provisional application No. 63/651,897, filed on May 24, 2024.

(51) Int. Cl. H10B 10/00; G11C 11/412; G11C 11/419; H01L 21/8238; H01L 27/092; H01L 29/06; H01L 29/423; H01L 29/66; H01L 29/775; H01L 29/786

(52) U.S. Cl. CPC H10B 10/12; G11C 11/412; G11C 11/419; H10D 30/014; H10D 30/43; H10D 30/6735; H10D 30/6757; H10D 62/121; H10D 84/017; H10D 84/038; H10D 84/85

(57) ABSTRACT

A method includes forming a front-side pass-gate transistor over a front-side of a substrate, wherein the front-side pass-gate transistor is comprised in a memory bit-cell, and is of a first conductivity type; forming a back-side pull-down transistor over a back-side of the substrate, wherein the back-side pull-down transistor is comprised in the memory bit-cell, and is of a second conductivity type opposite to the first conductivity type, and the back-side pull-down transistor is an oxide semiconductor transistor.

### PRIORITY CLAIM AND CROSS-REFERENCE

This application claims priority to U.S. Provisional Application Ser. No. 63/651,897, filed May 24, 2024, which is herein incorporated by reference.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a circuit diagram in accordance with some embodiments of the present disclosure.

FIG. 2A illustrates a perspective view of a semiconductor structure in accordance with some embodiments of the present disclosure.

FIG. 2B illustrates a cross-sectional view of obtained from the reference cross-sections A-A′ in FIG. 2A in accordance with some embodiments of the present disclosure.

FIG. 3A shows capacitances (aF) of bit line and word line of 6 transistors (6T) static random-access memory (SRAM) bit-cells with pull-down oxide semiconductor transistors in accordance with some embodiments of the present disclosure.

FIG. 3B shows via resistance (Ω) of each metal line (e.g., bit line/bit line bar, word line, and power supply voltage line) in the 6T SRAM bit-cells with pull-down oxide semiconductor transistors in accordance with some embodiments of the present disclosure.

FIG. 3C shows the access times of the 6T SRAM bit-cells with pull-down oxide semiconductor transistors in accordance with some embodiments of the present disclosure.

FIG. 3D shows power dissipations (or consumptions) (μW) of the 6T SRAM bit-cells with pull-down oxide semiconductor transistors in accordance with some embodiments of the present disclosure.

FIG. 3E shows the minimum write voltage (Vmin) of the 6T SRAM bit-cells with pull-down oxide semiconductor transistors in accordance with some embodiments of the present disclosure.

FIG. 3F shows Id-Vg curves of nanosheet n-type field-effect transistor (FET), nanosheet p-type FET, and nanosheet oxide semiconductor FET those are used in the simulation as shown in FIGS. 3A-3E in accordance with some embodiments of the present disclosure.

FIGS. 4A-24A, 25A, and 26-29A illustrate schematic views of intermediate stages in the formation of a semiconductor structure in accordance with some embodiments of the present disclosure.

FIGS. 24B, 25B, and 29B illustrate schematic views of intermediate stages in the formation of a semiconductor structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

In some embodiments, 6 transistors (6T) static random-access memory (SRAM) architectures can be impacted by increased parasitic capacitance and resistance, which may lead to higher power consumption and longer access times in these memory cells. Therefore, the present disclosure in various embodiments provides an improved SRAM bit-cell configuration, employing back-side oxide semiconductor pull-down transistors to enhance the performance, power efficiency, and area utilization of high-density 6T SRAM bit-cells. By relocating the pull-down transistors to the back-side of the semiconductor structure, the configuration can achieve improved electrical characteristics. Furthermore, the 6T SRAM bit-cell with two back-side oxide semiconductor pull-down transistors, coupled with front-side p-type metal-oxide-semiconductor (MOS) pass-gate and pull-up transistors can not only optimize the electrical paths and reduces parasitic effects but also shrink the cell area, enhancing overall chip density.

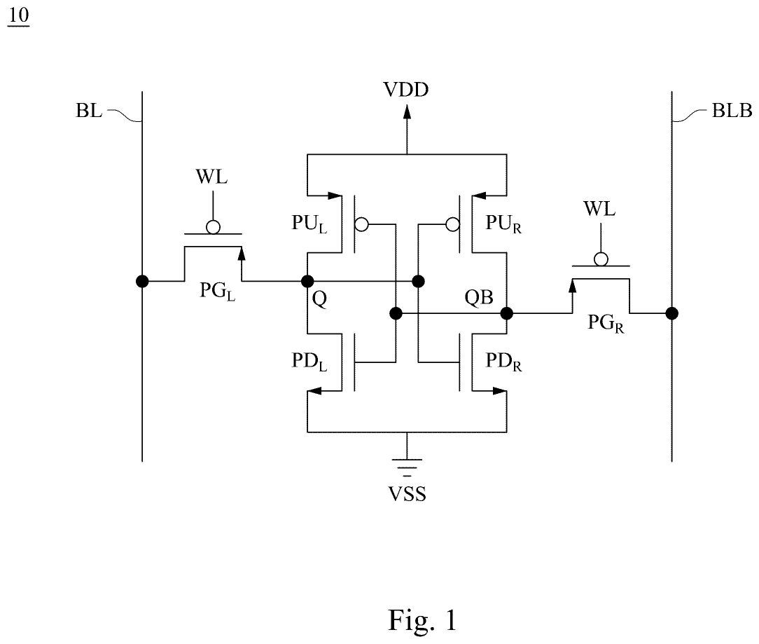

Reference is made to FIG. 1. FIG. 1 illustrates a circuit diagram in accordance with some embodiments of the present disclosure. As shown in FIG. 1, the SRAM bit-cell 10 includes pull-up transistors PU_{L} and PU_{R} and pass-gate transistors PG_{L}, and PG_{R}, which are of first conductivity type, and pull-down transistors PD_{L} and PD_{R}, which are second conductivity type opposite to the first conductivity type. By way of example and not limitation, the pull-up transistors PU_{L} and PU_{R} and pass-gate transistors PG_{L} and PG_{R} can be p-type Metal-Oxide-Semiconductor (PMOS) transistors, and pull-down transistors PD_{L} and PD_{R} can be n-type Metal-Oxide-Semiconductor (NMOS) transistors.

The gates of pass-gate transistors PG_{L} and PG_{R} are controlled by a word line WL that determines whether SRAM bit-cell 10 is selected or not. A latch formed of pull-up transistors PU_{L} and PU_{R} and pull-down transistors PD_{L} and PD_{R} stores a bit, wherein the complementary values of the bit are stored in storage data nodes Q and QB. The stored bit can be written into, or read from, SRAM bit-cell 10 through complementary bit lines including a bit line BL and a bit line bar BLB. SRAM bit-cell 10 can be powered through a positive power supply node CVdd that can have a positive power supply voltage. SRAM bit-cell 10 can be also connected to a power supply voltage node CVss, which may be an electrical ground. The transistors PU_{L} and PD_{L} form a first inverter INV1. Transistors PU_{R} and PD_{R} form a second inverter INV2. The first and second inverters INV1 and INV2 are cross-latched. For example, the input of the first inverter INV1 (e.g., gates of the transistors PU_{L} and PD_{L}) is connected to the output of the second inverter INV2 (e.g., drains of the transistors PU_{R} and PD_{R}), and the output of the first inverter INV1 (e.g., drains of the transistors PU_{L} and PD_{L}) is connected to the input of the second inverter INV2 (e.g., gates of the transistors PU_{R} and PD_{R}). The input of the first inverter INV1 is also connected to the transistor PG_{R}. The output of the first inverter is also connected to the transistor PG_{L}.

The sources of pull-up transistors PU_{L} and PU_{R} can be connected to positive power supply node CVdd. The sources of pull-down transistors PD_{L} and PD_{R} can be connected to the power supply voltage node CVss. The gates of transistors PU_{L} and PD_{L} can be connected to the drains of transistors PU_{R} and PD_{R}, which can form a connection node that can be referred to as a storage data node QB. The gates of transistors PU_{R} and PD_{R} can be connected to the drains of transistors PU_{L} and PD_{L}, which can form a connection node is referred to as a storage data node Q. A source/drain region of pass-gate transistor PG_{L} is connected to the bit line BL. A source/drain region of pass-gate transistor PG_{R} is connected to the bit line bar BLB.

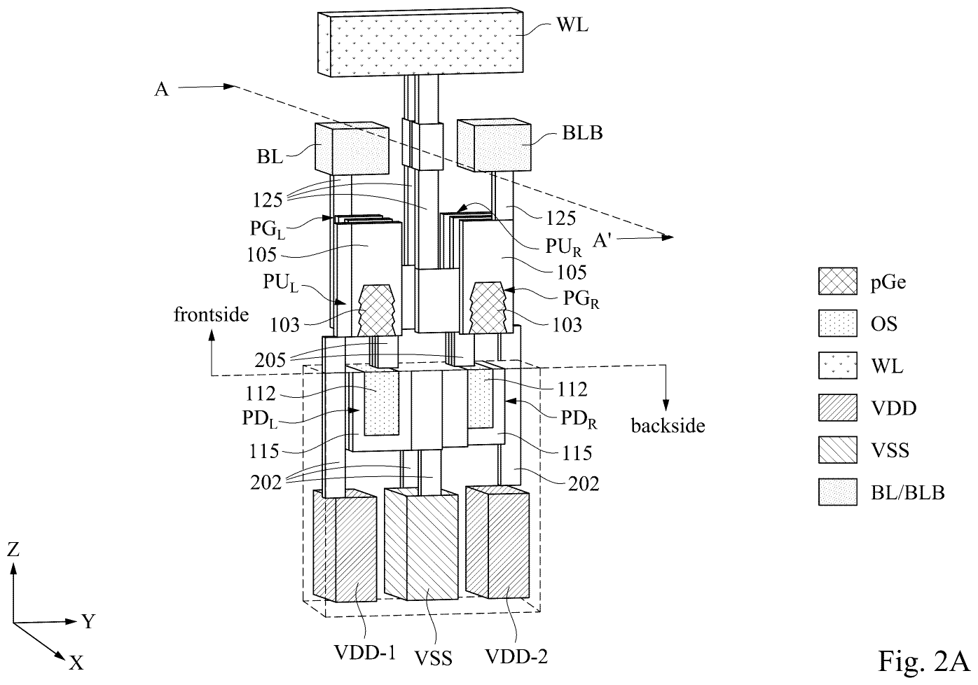

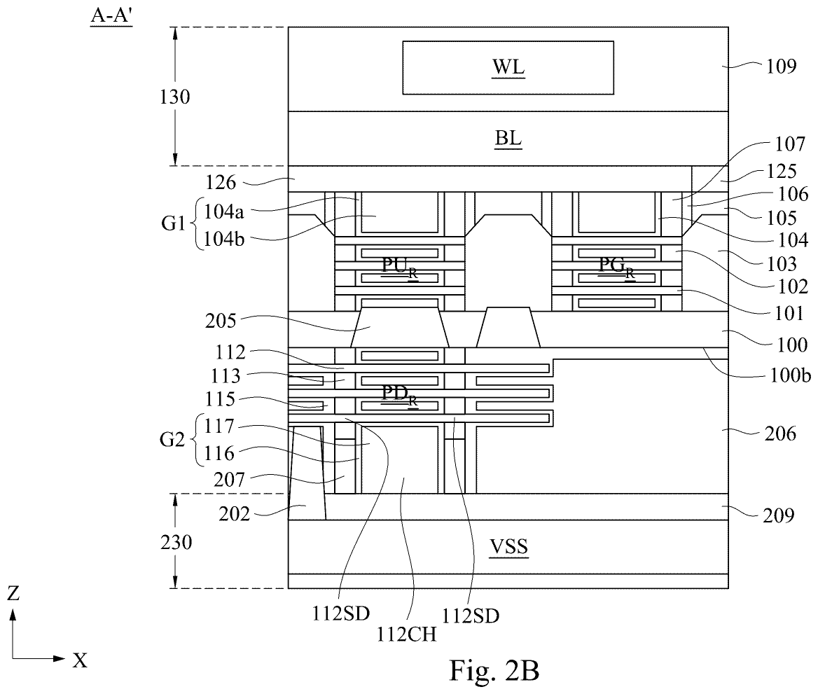

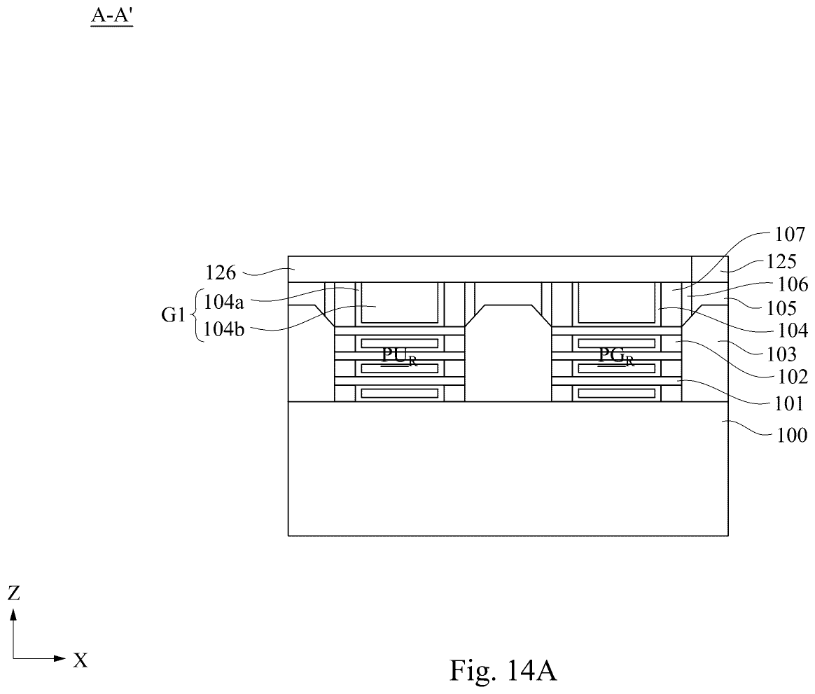

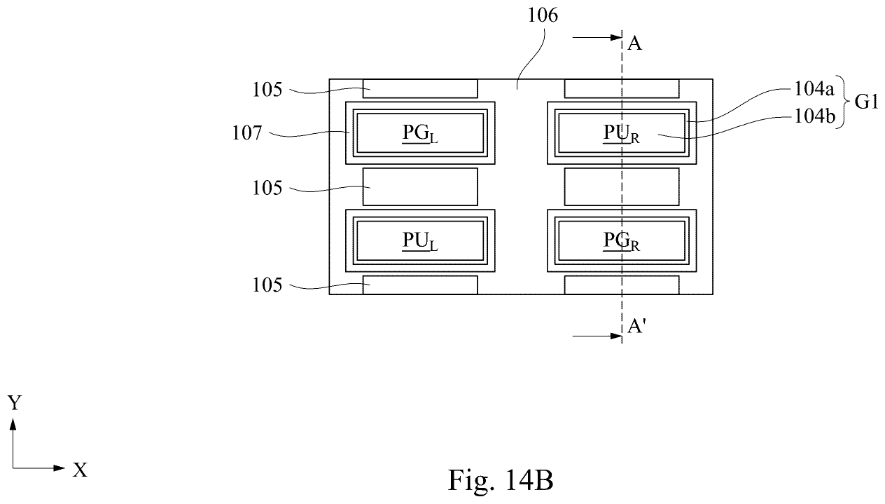

Reference is made to FIGS. 2A and 2B. FIG. 2A illustrates a perspective view of a semiconductor structure in accordance with some embodiments of the present disclosure. FIG. 2B illustrates a cross-sectional view of obtained from the reference cross-sections A-A′ in FIG. 2A in accordance with some embodiments of the present disclosure. The semiconductor structure can be a SRAM bit cell 10 that uses six transistors (6T). The semiconductor structure can include transistors PD_{L} and PD_{R} as bottom-tier (or back-side) transistors and the transistors PU_{L}, PU_{R}, PG_{L}, and PG_{R} (see FIG. 14B) as top-tier (or front-side) transistors. In some embodiments, the transistors PD_{L}, PD_{R}, PU_{L}, PU_{R}, PG_{L}, and PG_{R} can be positioned at more than 2-tier. In some embodiments, the transistors of the SRAM bit cell 10 can include various channel geometries such as nanosheets, FinFETs, and nanowires.

As shown in FIGS. 2A and 2B, the transistors PD_{L} and PD_{R} each includes a channel material layer 112 (see FIG. 2B) having a channel region 112CH and source/drain regions 112SD on opposite sides of the channel region 112CH, and includes a gate structure G2 (see FIG. 2B) wrapping around the channel material layer 112. In some emobodiments, the transistors PD_{L} and PD_{R} can be oxide semiconductor (OS) transistors being of a first conductivity type. The transistors PU_{L}, PU_{R}, PG_{L}, and PG_{R} each includes the channel layer 101 (see FIG. 2B), the source/drain regions 103 on opposite sides of the channel layer 101 and connected to the channel layer 101, and the gate structure G1 (see FIG. 2B) wrapping around the channel layer 101. In some emobodiments, the transistors PD_{L} and PD_{R} can be metal-oxide-semiconductor (MOS) transistors being of a second conductivity type different than the first conductivity type of the transistors PD_{L} and PD_{R}. By way of example and not limitation, the transistors PD_{L} and PD_{R} may be n-type transistors, and the transistors PU_{L}, PU_{R}, PG_{L}, and PG_{R} may be p-type transistors.

By situating the oxide semiconductor pull-down transistors PD_{L} and PD_{R} on the back-side of the semiconductor structure, the SRAM bit-cell 10 can reduces the parasitic capacitance and resistance that may affect the bit line BL, the bit line bar BLB, the word line WL, the voltage source lines VDD-1 and VDD-1, and the ground line VSS. Lower parasitic values can lessen the undesirable electrical loading effects, which can degrade the performance of the memory cell. Additionally, the back-side placement of the pull-down transistors PD_{L} and PD_{R} can minimize dynamic power consumption, which is a function of the formula CV² (where C is capacitance and V is voltage). By decreasing the capacitance involved in the memory bit-cell's operation, the energy required for charging and discharging the capacitive elements can be reduced. This back-side placement of the pull-down transistors PD_{L} and PD_{R} can also allow the SRAM bit-cell 10 to operate effectively at lower voltages. Operating at lower voltages can further reduce the power consumption, making the SRAM bit-cell 10 more energy-efficient and suitable for power-sensitive applications. Furthermore, this arrangement of the pull-down transistors PD_{L} and PD_{R} can aid in cutting down the delays linked to parasitic capacitance and resistance. In some embodiments, delays in semiconductor devices may stem from the time it takes to charge and discharge capacitive loads, which can be exacerbated by higher resistance and capacitance. Therefore, by mitigating the parasitic effects, the SRAM bit-cell 10 can contribute to faster access times, which in turn allows for improving the throughput of the SRAM bit-cell 10, enabling quicker data retrieval and storage, and enhancing the overall performance of the SRAM bit-cell 10.

The placement of the pull-down transistors PD_{L} and PD_{R} on the back-side of the semiconductor structure can enhance the integration and manufacturing process, in terms of compatibility with the back-end-of-line processes used on the front-side of the semiconductor structure. The active layer (e.g., channel material layer 112) of the pull-down transistors PD_{L} and PD_{R} can be constructed from an amorphous oxide semiconductive material, such as indium gallium zinc oxide (IGZO). The amorphous oxide semiconductive material may include high transparency and flexibility in addition to its semiconductive capabilities. The amorphous oxide semiconductive material can have ability to be processed at relatively low temperatures (e.g., below about 400° C., such as about 100, 150, 200, 250, 300, 350, or 400° C.), ensuring that the manufacturing of the pull-down transistors PD_{L} and PD_{R} does not interfere with or damage the layers and components already in place. Specifically, placing the pull-down transistors PD_{L} and PD_{R} on the back-side of the semiconductor structure and using a low-temperature process material can allow the pull-down transistors PD_{L} and PD_{R} to be formed without compromising the integrity of the front-side structures and without the risk of exceeding thermal budgets set for earlier manufacturing stages.

In some embodiments, the transistors PD_{L} and PD_{R} can be situated at a first level height, and the transistors PU_{L}, PU_{R}, PG_{L}, and PG_{R} can be situated at a second level height higher than the first level height. By way of example but not limitation, the transistor PU_{L} can be over the transistor PD_{L}, and the transistor PU_{R} can be over the transistor PD_{R}. In some embodiments, the channel layer 101 and/or the channel region 112CH of the channel material layer 112 can be interchangeable referred to as an active layer, a channel pattern, a channel region, a channel line, a semiconductive layer, or a semiconductive nanostructure. In some embodiments, the source/drain region 103 and/or the source/drain regions 112SD of the channel material layer 112 can be interchangeably referred to as a source/drain pattern, an epitaxial pattern, a source/drain structure, or an epitaxial structure. In some embodiments, the gate structure G1 and/or the gate structure G2 can be interchangeable referred to as a gate, a gate pattern, a gate strip, a gate layer, a gate layer, or a functional gate.

In FIGS. 2A and 2B, a first one of the source/drain regions 103 of the transistor PU_{L} can be electrically connected to the underlying voltage source line VDD-1 through a vertical contact 202 (see FIG. 2A), and a second one of the source/drain regions 103 of the transistor PU_{L} can be electrically connected to the gate structure G1 of the transistor PU_{R}. A first one of the source/drain regions 103 of the transistor PU_{R} can be electrically connected to the underlying voltage source line VDD-2 through a vertical contact 202 (see FIG. 2A), and a second one of the source/drain regions 103 of the transistor PU_{R} can be electrically connected to the gate structure G1 of the transistor PU_{L}.

In FIGS. 2A and 2B, a first one of the source/drain regions 112SD of the transistor PD_{L} is electrically connected to the underlying ground line VSS through the contact 202, a second one of the source/drain regions 112SD (see FIG. 2B) of the transistor PD_{L} is electrically connected to a first source/drain node (e.g., source/drain region 103) of the transistor PG_{L} through the back-side contacts 205, in which the transistor PU_{L} and the transistor PG_{L} can share the same source/drain region 103. Additionally, the second one of the source/drain regions 112SD can be further electrically connected to the gate structure G2 of the transistor PD_{R}. The gate structure G2 of the transistor PD_{L} is electrically connected to the gate structure G1 of the transistor PU_{L} through the back-side contact 205.

Similarly, a first one of the source/drain regions 112SD of the transistor PD_{R} is electrically connected to the underlying ground line VSS through the contact 202, a second one of the source/drain regions 112SD of the transistor PD_{R} is electrically connected to a first source/drain node (e.g., source/drain region 103) of the transistor PG_{R} through the back-side contact 205, in which the transistor PU_{R} and the transistor PG_{R} can share the same source/drain region 103. Additionally, the second one of the source/drain regions 112SD can be further electrically connected to the gate structure G2 of the transistor PD_{L}. The gate structure G2 of the transistor PD_{R} is electrically connected to the gate structure G1 of the transistor PU_{R} through the back-side contact 205.

In FIGS. 2A and 2B, a second one of source/drain regions 103 of the transistor PG_{L} is electrically connected to the overlying bit line BL through the contact 105. The gate structure G1 of the transistor PG_{L} can be electrically connected to the overlying word line WL through the contact 105. Similarly, a second one of source/drain regions 103 of the transistor PG_{R} is electrically connected to the overlying bit line BLB through the contact 105. The gate structure G1 of the transistor PG_{R} can be electrically connected to the overlying word line WL through the contact 105.

As shown in FIGS. 2A and 2B, a footprint of the transistors PD_{L} can overlap with a footprint of the first write transistor PU_{L}, and a footprint of the transistors PD_{R} can overlap with a footprint of the first write transistor PU_{R}. A footprint of a transistor can be a vertical projection of the transistor on a substrate. On the other hand, footprints of the channel layers 101 of the transistor PD_{L} can overlap with footprints of the channel material layers 112 of the transistor PU_{L}, and footprints of the channel layers 101 of the transistor PD_{R} can overlap with footprints of the channel material layers 112 of the transistor PU_{R}.

In some embodiments, the voltage source line VDD-1/VDD-2 and/or the ground line VSS can be interchangeable referred to as a backside power line. In some embodiments, the voltage source lines VDD-1 and VDD-2 and ground line VSS can be collectively referred to a backside power delivery network (BSPDN). In some embodiments, by integrating backside power delivery network and complementary field-effect transistor (FET) technologies, the implementation of the multi-port CFET SRAM can have a reduction in routing complexity. This approach not only streamlines the internal architecture of the SRAM bit-cell 10 but also enhances overall circuit efficiency and reliability. In some embodiments, the voltage source lines VDD-1 and VDD-2 and the ground line VSS can be positioned at back-end-of-line (BEOL) over a front-side of the SRAM bit-cell 10.

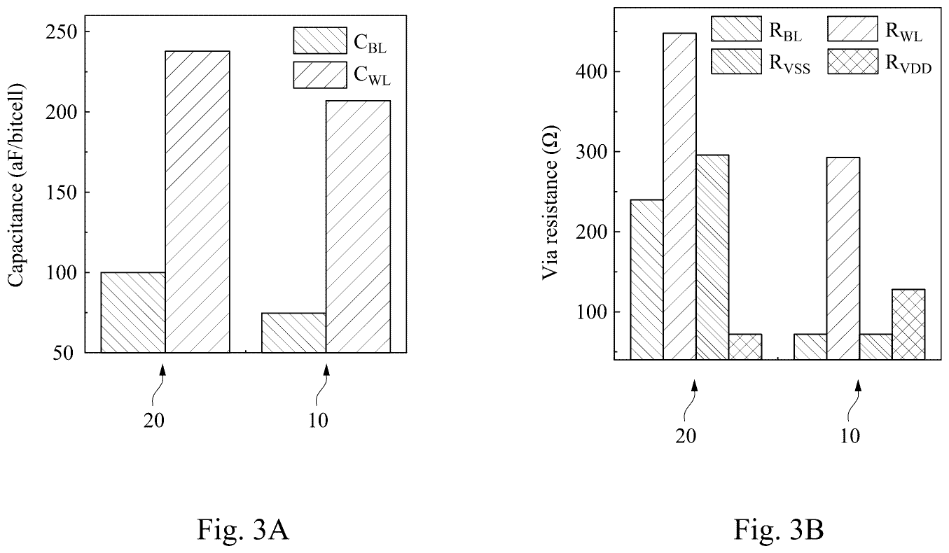

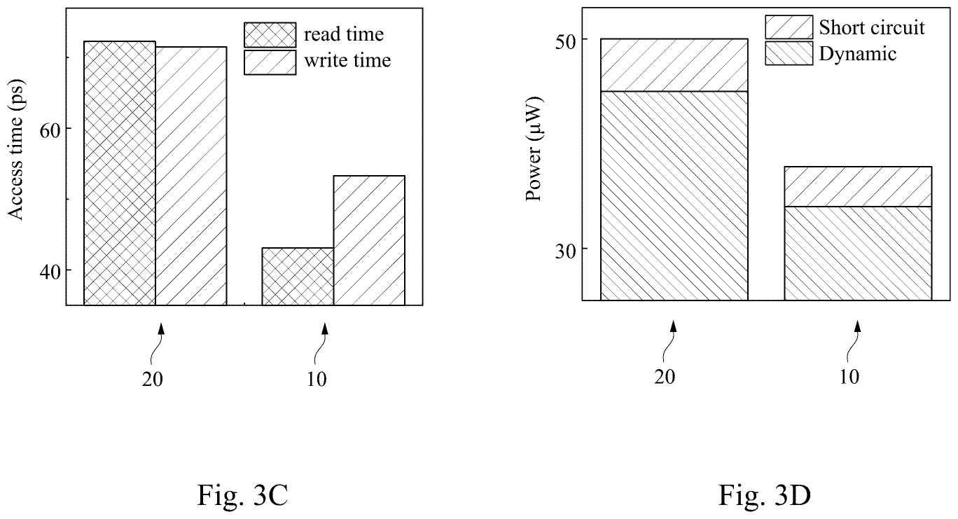

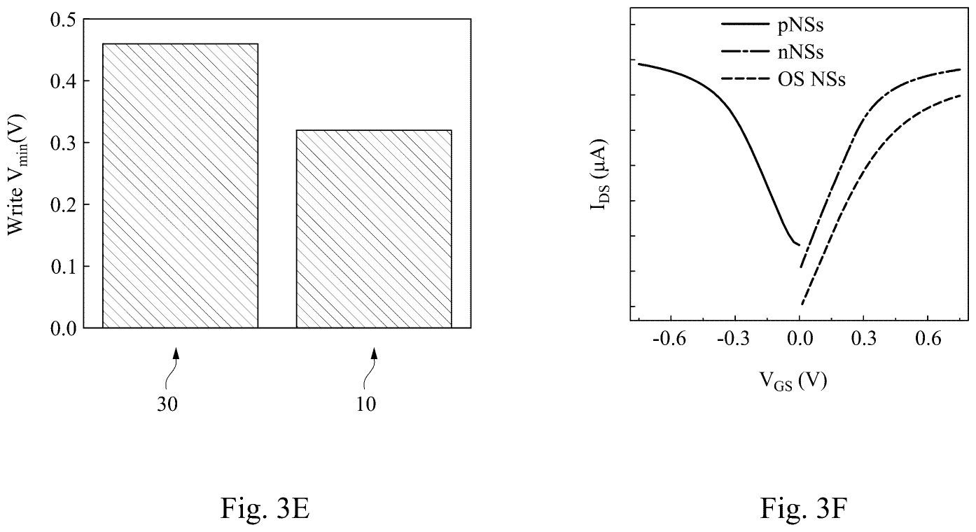

The SRAM bit-cells 10 can offer enhancements over two models (e.g., SRAM bit-cells 20 and 30) by optimizing transistor placement. Technology computer-aided design (TCAD) simulations can be performed on the SRAM bit-cells 10, 20, and 30 as shown in FIGS. 3A-3F. Reference is made to FIGS. 3A-3F. The SRAM bit-cell 10 and the SRAM bit-cells 20 both describe a 6T SRAM bit-cell structure that includes power supply voltage lines (e.g., voltage source lines VDD-1, VDD-2, and ground line VSS), with two p-type MOS transistors (e.g., transistors PU_{L}, PU_{R}, PG_{L}, and PG_{R}) for pull-up and pass-gate functions positioned directly above these lines. Additionally, the bit line BL, the bit line bar BLB, and a word line WL can be structured above the p-type MOS transistors, organizing the circuitry vertically. The difference between the SRAM bit-cells 10 and 20 may lie in the placement of the pull-down transistors PD_{L} and PD_{R}. The SRAM bit-cell 20 can have two pull-down oxide semiconductor transistors positioned between the p-type MOS transistors and the bit lines, located at the back-end-of-line (BEOL) on the front side of the semiconductor structure. The SRAM bit-cell 10 can have two pull-down oxide semiconductor transistors (i.e., transistors PD_{L} and PD_{R}) positioned between the power supply voltage lines and the p-type MOS transistors on the back side of the semiconductor structure, optimizing space and reducing interference.

The SRAM bit-cell 30, which can share the same architecture as the SRAM bit-cell 10, differs in transistor composition and type. The SRAM bit-cell 30 can have six transistors being MOS transistors, arranged at the same level height, and creating a 6T footprint on the substrate. The pass-gate transistors in the SRAM bit-cell 30 are n-type, contrasting with the p-type pass-gate transistors (i.e., transistors PD_{L} and PD_{R}) in the SRAM bit-cell 10. These differences may impact the performance characteristics and efficiency of SRAM bit-cells.

Reference is made to FIG. 3A. FIG. 3A illustrates the capacitance simulations for the bit line BL, the bit line bar BLB, and the word line WL in two versions of a 6T SRAM bit-cell, specifically the SRAM bit-cells 10 and 20, which incorporate pull-down oxide semiconductor transistors. FIG. 3A can demonstrate that placing pull-down oxide semiconductor transistors (e.g., transistors PD_{L} and PD_{R}) on the back-side of the semiconductor structure can effectively reduce the capacitance values CBL for the bit line and the capacitance values C_{WL} the word line. In contrast, the SRAM bit-cell 20 positions these transistors on the back-end-of-line at the front-side of the semiconductor structure, resulting in higher capacitance. Therefore, the back-side stacking in the SRAM bit-cell 10 can ensure lower capacitance for the bit line, the bit line bar, and the word line, enhancing the overall efficiency and performance of the SRAM bit-cell 10.

Reference is made to FIG. 3B. FIG. 3B illustrates the via resistance simulations for various metal lines, including the bit line BL, the bit line bar BLB, the word line WL, and the power supply voltage lines (e.g., ground line VSS and voltage source lines VDD-1, VDD-2) in the 6T SRAM bit-cell configuration. FIG. 3B shows how the placement of pull-down oxide semiconductor transistors on the back-side of the semiconductor structure, as implemented in the SRAM bit-cell 10, can contribute to decrease via resistance. This configuration can allow for shorter vias connecting the signal lines such as the bit line, bit line bar, and the word line. The shortened vias can reduce the overall resistance encountered in these pathways, enhancing electrical performance. Consequently, the SRAM bit-cell 10 can exhibit lower via resistance values RBL, RWL, RVDD, Rvss for these metal lines compared to the SRAM bit-cell 20, where transistors are placed at the front-side, resulting in longer via paths and higher resistance.

Reference is made to FIG. 3C. FIG. 3C illustrates the access times (e.g., read time, write time) for SRAM bit-cells 10 and 20. FIG. 3A can demonstrate that the SRAM bit-cell 10, which positions the transistors PD_{L} and PD_{R} on the back-side of the semiconductor structure, can benefit from reduced time delays compared to the SRAM bit-cell 20, where the transistors PD_{L} and PD_{R} are located on the back-end-of-line at the front-side. The improved access times in the SRAM bit-cell 10 may be attributed to the reduced parasitic capacitance and resistance, as illustrated in FIGS. 3A and 3B. Consequently, the SRAM bit-cell 10 can exhibit faster read and write speeds to have quicker data access and processing compared to the SRAM bit-cell 20.

Reference is made to FIG. 3D. FIG. 3D illustrates the power dissipation levels for the SRAM bit-cells 10 and 30. FIG. 3D can demonstrate that positioning the transistors PD_{L} and PD_{R} on the back-side of the semiconductor structure, as illustrated in the SRAM bit-cell 10, can lead to reduced power dissipation compared to the SRAM bit-cell 20, where transistors are located on the back-end-of-line at the front-side. The reduction in power dissipation in the SRAM bit-cell 10 can be due to decreased dynamic power consumption, which follows the formula CV², where C is capacitance and V is voltage. Additionally, the minimized parasitic capacitance and resistance associated with the back-side transistor placement can contribute to lower short circuit power, which occurs when n-type field-effect transistors (FET) and p-type FETs are activated simultaneously. Consequently, the SRAM bit-cell 10 can consumes less power than the SRAM bit-cell 20, enhancing overall energy efficiency within the system.

Reference is made to FIG. 3E. FIG. 3E illustrates a comparison between the minimum write voltage (Vₘᵢₙ, near threshold voltage) for successful data storage in the SRAM bit-cells 10 and 30. FIG. 3E can demonstrate that the SRAM bit-cell 10 can achieve a lower near-threshold write voltage, about 0.2-0.4V, such as about 0.2, 0.25, 0.3, 0.5, or 0.4V, which can be lower than that used in the SRAM bit-cell 30, such that the SRAM bit-cell 10 can operate effectively at lower voltages, enhancing energy efficiency during write operations. FIG. 3E shows a higher minimum read voltage of the SRAM bit-cell 10 compared to the SRAM bit-cell 30. This may be attributed to the characteristics of the pull-down oxide semiconductor transistors used in the SRAM bit-cell 10, which are weaker than the p-type pass-gate MOS transistors used in the SRAM bit-cell 30, and results in a slightly increased threshold voltage to read data reliably from the SRAM bit-cell 10. The overall performance in terms of power efficiency and lower write voltage thresholds can demonstrate advancement in SRAM bit-cell 10.

Reference is made to FIG. 3F. FIG. 3F illustrates drain current versus gate voltage (Id-Vg) curves for three types of field-effect transistors (FETs) used in the simulations: nanosheet n-type (nNS), nanosheet p-type (pNS), and nanosheet oxide semiconductor (OS NS) FETs. These Id-Vg curves can be used for understanding the electrical characteristics and performance of each transistor type within the SRAM cell configurations discussed in FIGS. 3A-3E. The Id-Vg curves can illustrate how the oxide semiconductor FET (OS NS), when compared to the nanosheet n-type FET (nNS), can exhibit lower electron mobility. The electron mobility can influence the speed at which the transistor can switch between on and off states, impacting the overall performance of the SRAM bit-cells. The attributes of the oxide semiconductor FET, such as potentially better stability or lower leakage, can make it a choice depending on the overall system requirements and constraints.

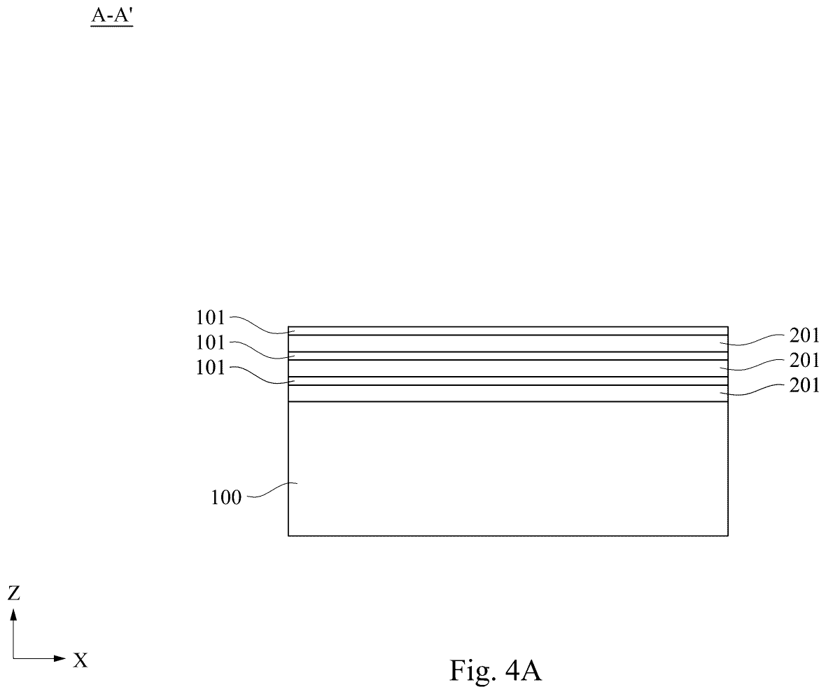

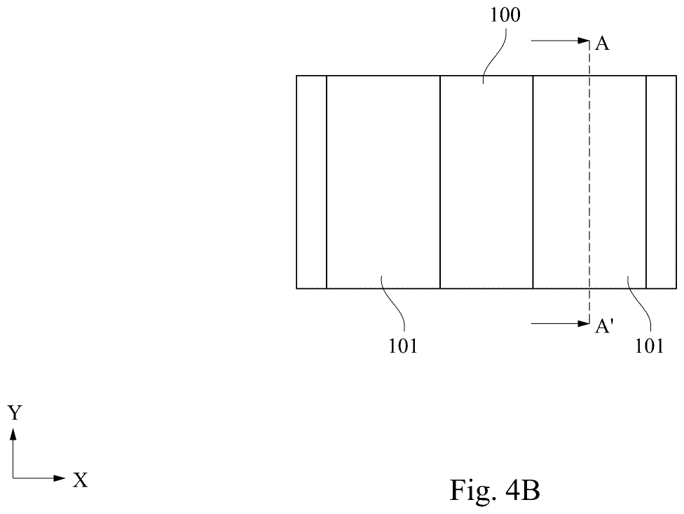

Reference is made to FIGS. 4A-24A, 25A, and 26-29A. FIGS. 4A-24A, 25A, and 26-29A illustrate schematic views of intermediate stages in the formation of a semiconductor structure in accordance with some embodiments of the present disclosure. FIGS. 4A, 5-14A, 15-24A, 25A, and 26-29A illustrate cross-sectional views obtained from the reference cross-section A-A′ in the formation of the semiconductor structure in accordance with some embodiments. FIGS. 4B and 14B illustrate top views of the formation of the semiconductor structure in accordance with some embodiments. It is understood that additional operations can be provided before, during, and after the processes shown by FIGS. 4A-24A, 25A, and 26-29A, and some of the operations described below can be replaced or eliminated, for additional embodiments of the method. The order of the operations/processes may be interchangeable.

Reference is made to FIGS. 4A and 4B. An epitaxial stack is formed over a substrate 100. In some embodiments, the substrate 100 may include silicon (Si). Alternatively, the substrate 100 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 100 may include a semiconductor-on-insulator (SOI) structure such as a buried dielectric layer. Also alternatively, the substrate 100 may include a buried dielectric layer such as a buried oxide (BOX) layer, such as that formed by a method referred to as separation by implantation of oxygen (SIMOX) technology, wafer bonding, SEG, or another appropriate method.

The epitaxial stack can include sacrificial layers 201 of a first composition interposed by a channel layer 101 of a second composition. The first and second compositions can be different. In some embodiments, the sacrificial layers 201 may be made of SiGe and have a different germanium atomic concentration than the channel layer 101. In some embodiments, the sacrificial layer 201 can have a greater germanium atomic concentration than the channel layer 101. In some embodiments, the channel layer 101 may be made of silicon (Si). By way of example but not limitation, the sacrificial layer 201 may have a germanium atomic concentration in a range from about 10 to 90%, such as about 10, 20, 30, 40, 50, 60, 70, 80, 90%. However, other embodiments are possible including those that provide for the first and second compositions having different etch selectivity.

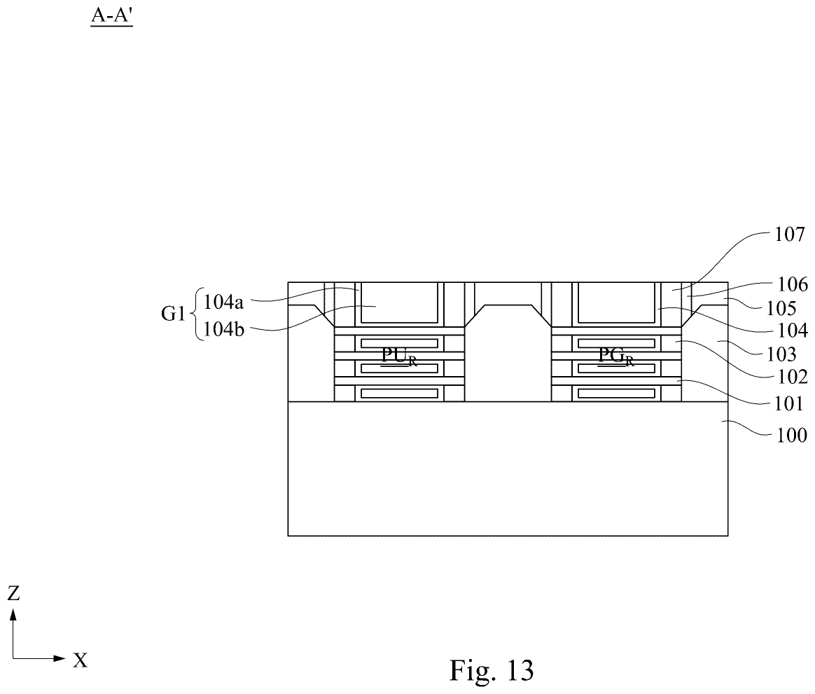

The use of the channel layer 101 to define a channel of a device is further discussed below. It is noted that three layers of the channel layer 101 can be arranged as illustrated in FIG. 4A, which is for illustrative purposes only and not intended to be limiting beyond what is specifically recited in the claims. It can be appreciated that any number of sacrificial layers 201 and/or the channel layers 101 can be formed in the epitaxial stack; the number of layers depending on the desired number of channels regions for the transistor. In some embodiments, the number of the channel layer 101 can be between about 1 and 101, such as about 1, 2, 3, 4, 5, 10, 15, 20, 25, 30, 35, 40,45, 50, 55, 60, 65, 70, 75, 80, 85, 90, 95, 100, or 101. As described in more detail below, the channel layer 101 may serve as a channel region for a subsequently-formed semiconductor device and the thickness is chosen based on device performance considerations. In some embodiments, the channel layer 101 can have a thickness in a range from about 0.5 to 50 nm, such as about 0.5, 5, 10, 15, 20, 25, 30, 35, 40, 45, or 50 nm. In some embodiments, the channel layer 101 can have a width in a range from about 5 to 100 nm, such as about 5, 10, 20, 30, 40, 50, 60, 70, 80, 90, or 100 nm. In some embodiments, the channel layer 101 can have a length in a range from about 5 to 500 nm, such as about 50, 100, 150, 200, 250, 300, 350, 400, 450, or 500 nm. In some embodiments, the channel layer 101 can have a geometry being a square, rectangle, diamond, or any suitable cross-sectional profile taken along a lengthwise direction of the gate structure G1 (see FIG. 13). The sacrificial layers 201 in the channel region may eventually be removed and serve to define a vertical distance between adjacent channel region(s) for a subsequently-formed multi-gate device and the thickness is chosen based on device performance considerations. In some embodiments, a vertical distance between adjacent channel layers is in a range from about 5 to 50 nm, such as about 5, 10, 15, 20, 25, 30, 35, 40, 45, or 50 nm.

By way of example, epitaxial growth of the layers of the epitaxial stack may be performed by a molecular beam epitaxy (MBE) process, a metalorganic chemical vapor deposition (MOCVD) process, and/or other suitable epitaxial growth processes. In some embodiments, the epitaxially grown layers such as, the channel layer 101 can include the same material as the substrate 100. In some embodiments, the sacrificial layers 201 and channel layer 101 can include different materials than the substrate 100. As stated above, in at least some examples, the sacrificial layers 201 can include epitaxially grown silicon germanium (SiGe) layers, and the channel layers 101 can include an epitaxially grown silicon (Si) layer. Alternatively, in some embodiments, either of the sacrificial layer 201 and the channel layer 101 may include other materials such as germanium, tin, a compound semiconductor such as silicon carbide, gallium arsenide, gallium phosphide, indium phosphide, indium arsenide, and/or indium antimonide, an alloy semiconductor such as SiGe, GeSn, GaAsP, AlInAs, AlGaAs, InGaAs, GaInP, and/or GaInAsP, III-V, or combinations thereof. In some embodiments, the channel layer 101 can include IV-based material, such as Si, Ge, Sn, Si₁₋ₓGeₓ, Ge_{1-y}Sn_{y}, Si_{1-x-y}GeₓSn_{y}, other suitable materials, or combinations thereof. In some embodiments, the channel layer 101 can include III-V-based material, an oxide semiconductor material, 2D (two dimensional) material, other suitable materials, or combinations thereof. As discussed, the materials of the sacrificial layer 201 and the channel layer 101 may be chosen based on providing differing oxidation and/or etching selectivity properties.

Subsequently, the epitaxial stack includes the channel layer 101 and the sacrificial layers 201 can be patterned, such that the channel layer 101 and the sacrificial layers 201 or portions thereof may be formed nanostructures as shown in FIG. 4B. Specifically, the channel layer 101 may be formed nanostructure channel(s) of the nanostructure transistor. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are nanosheets, nanowires, nanoslabs, or nanorings, depending on their geometry. The patterned channel layer 101 and the sacrificial layers 201 may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer can be formed over the substrate 100 and patterned using a photolithography process. Spacers are formed alongside the patterned sacrificial layer using a self-aligned process. The sacrificial layer is then removed. The etching process can include dry etching, wet etching, reactive ion etching (RIE), and/or other suitable processes.

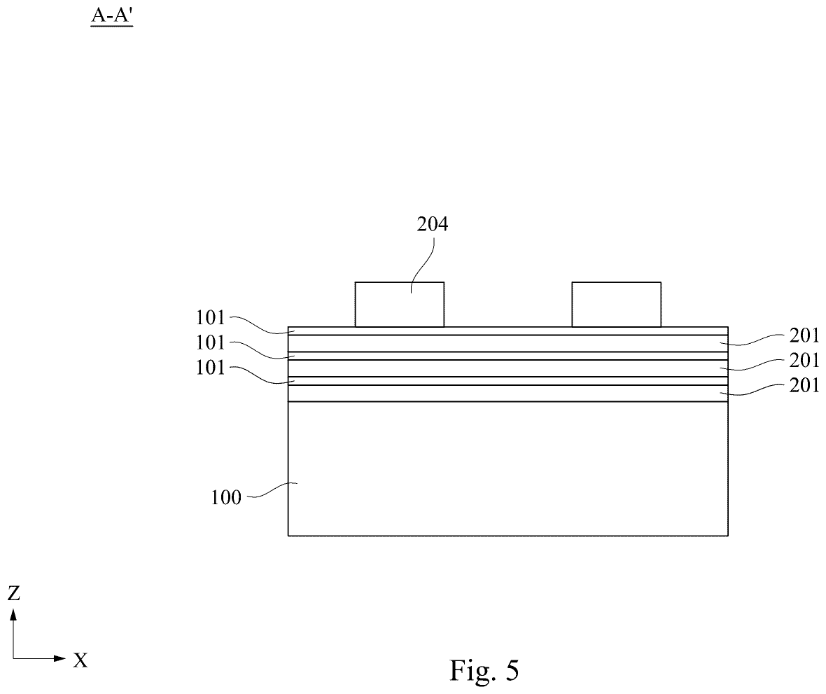

Reference is made to FIG. 5. Dummy gate layers 204 can be formed over the epitaxial stack as shown in FIG. 5. Portions of the channel layer 101 underlying the dummy gate layers 204 may be referred to as the channel regions. Dummy gate formation operation forms the dummy gate layer 204 and the hard mask layer (not shown) over the dummy gate layer 204. The hard mask layer can be then patterned, followed by patterning the dummy gate layer 204 by using the patterned hard mask layer as an etch mask. The etch process may include a wet etch, a dry etch, and/or combinations thereof.

In some embodiments, the dummy gate layer 204 may include polycrystalline-silicon (poly-Si), poly-crystalline silicon-germanium (poly-SiGe), metallic nitrides, metallic silicides, metallic oxides, or metals. In some embodiments, the dummy gate layer 204 may include a metal-containing material such as TiN, TaN, TaC, Co, Ru, Al, combinations thereof, or multi-layers thereof. In some embodiments, the dummy gate layer 204 may be deposited by CVD, physical vapor deposition (PVD), sputter deposition, or other techniques suitable for depositing conductive materials. In some embodiments, the dummy gate layer 204 can be interchangeably referred to a dummy gate, a dummy gate pattern, a dummy gate strip, an isolation structure, or a dielectric gate.

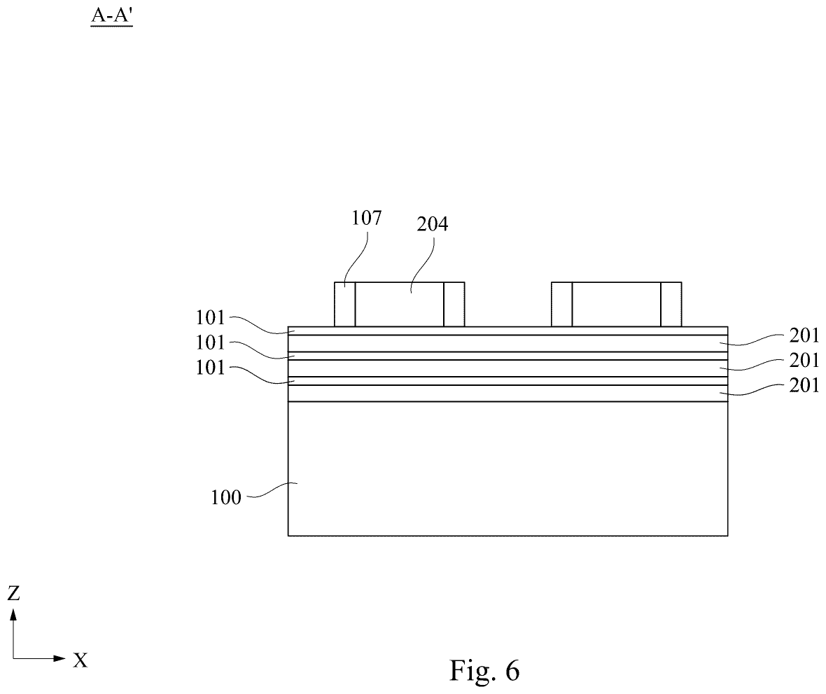

Reference is made to FIG. 6. Gate spacers 107 can be formed on sidewalls of the dummy gate layer 204. Specifically, a spacer material (not shown) can be deposited over the substrate 100. The spacer material may be a conformal layer on the topmost channel layer 101 and the dummy gate layers 204. The spacer material may include a dielectric material such as silicon oxide, silicon nitride, silicon carbide, silicon oxynitride, SiCN films, silicon oxycarbide, SiOCN films, and/or combinations thereof. In some embodiments, the spacer material can include multiple layers, such as a first spacer layer and a second spacer layer formed over the first spacer layer. Subsequently, an anisotropic etching process can be then performed on the deposited spacer material to expose the topmost channel layer 101 and the dummy gate layers 204. Portions of the spacer material directly on the dummy gate layers 204 and on the topmost channel layer 101 not covered by the dummy gate layers 204 may be completely removed by this anisotropic etching process. Portions of the spacer material on sidewalls of the dummy gate layer 204 may remain, forming gate spacers 107.

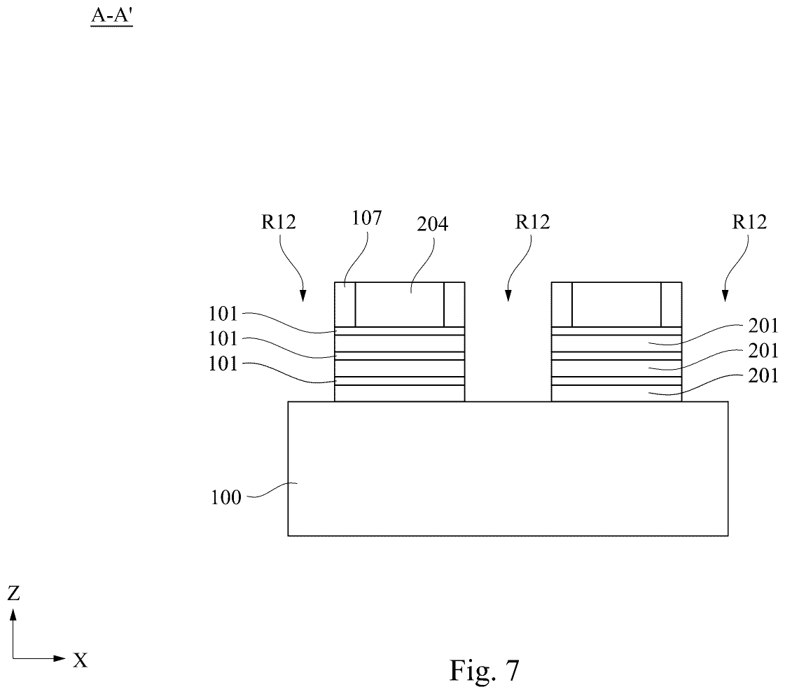

Reference is made to FIG. 7. Exposed portions of the patterned channel layer 101 and the patterned sacrificial layers 201 that extend laterally beyond the gate spacers 107 are etched by using, for example, an anisotropic etching process that uses the dummy gate layer 204 and the gate spacers 107 as an etch mask, resulting in recesses R12 into the channel layers 101 and the sacrificial layers 201. After the anisotropic etching, end surfaces of the patterned channel layer 101 and the patterned sacrificial layers 201 and respective outermost sidewalls of the gate spacers 107 are substantially coterminous, due to the anisotropic etching. In some embodiments, the anisotropic etching may be performed by a dry chemical etch with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

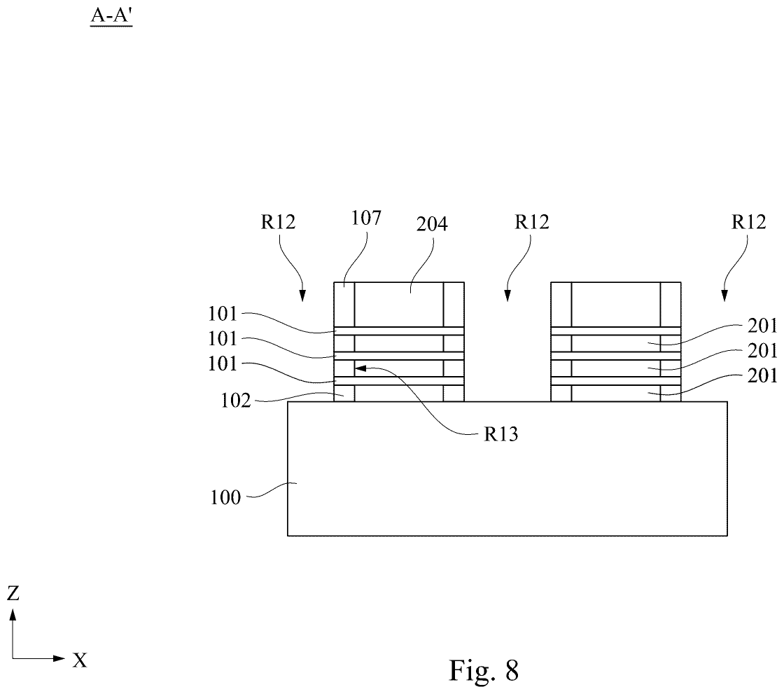

Reference is made to FIG. 8. The patterned sacrificial layers 201 can be laterally or horizontally recessed by using suitable etch techniques, resulting in lateral recesses R13. This operation may be performed by using a selective etching process. By way of example and not limitation, the sacrificial layers 201 can be made of SiGe and the channel layer 101 can be made of silicon allowing for the selective etching of the sacrificial layers 201. In some embodiments, the selective dry etching etches SiGe at a faster etch rate than it etches Si. As a result, the patterned channel layer 101 can laterally extend past opposite end surfaces of the patterned sacrificial layers 201.

Subsequently, inner spacers 102 can be filled in the recesses R13, respectively. For example, spacer material layers can be formed to fill the recesses R13 left by the lateral etching of the sacrificial layers 201 discussed above. The spacer material layer may be a low-k dielectric material, such as SiO₂, SiN, SiC, SiON, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes. After the deposition of the spacer material layer, an anisotropic etching process may be performed to trim the deposited spacer material layer, such that portions of the deposited spacer material layer that fill the recesses R13 left by the lateral etching of the sacrificial layers 201 are left. After the trimming process, the remaining portions of the deposited spacer material are denoted as inner spacers 102 in the recesses R13. The inner spacers 102 serve to isolate metal gates from source/drain regions formed in subsequent processing.

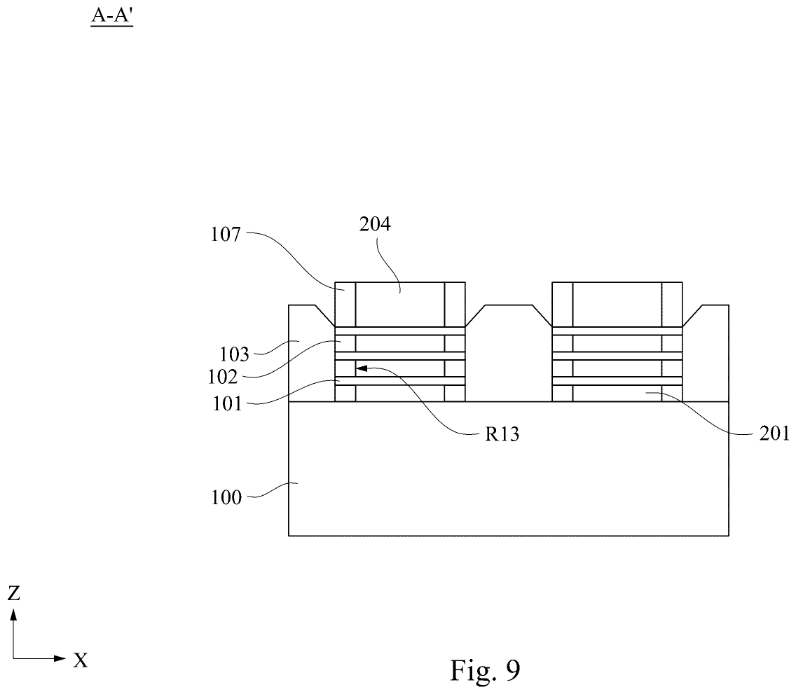

Reference is made to FIG. 9. Source/drain regions 103 are formed in the recesses R12 and connected to the channel layer 101. The source/drain regions 103 may be formed by performing an epitaxial growth process that provides an epitaxial material over the substrate 100. During the epitaxial growth process, the dummy gate layer 204, the gate spacers 107, and the inner spacers 102 limit the source/drain regions 103 to the substrate 100 and the channel layer 101. In some embodiments, the lattice constants of the source/drain regions 103 are different from the lattice constant of the channel layer 101, so that the channel layer 101 can be strained or stressed by the source/drain regions 103 to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the channel layer 101.

In some embodiments, the source/drain regions 103 may include Si, Ge, Sn, Si₁₋ₓGeₓ, Si_{1-x-y}GeₓSn_{y}, GaAs, AlGaAs, GaAsP, SiP, or other suitable material. The source/drain regions 103 may be in-situ doped during the epitaxial process by introducing doping species including: p-type dopants, such as boron or BF₂; n-type dopants, such as phosphorus or arsenic; and/or other suitable dopants including combinations thereof. If the source/drain regions 103 are not in-situ doped, an implantation process (i.e., a junction implant process) is performed to dope the source/drain regions 103. In some embodiments, the source/drain regions 208 can be of a p-type transistor and include SiGeB and/or GeSnB.

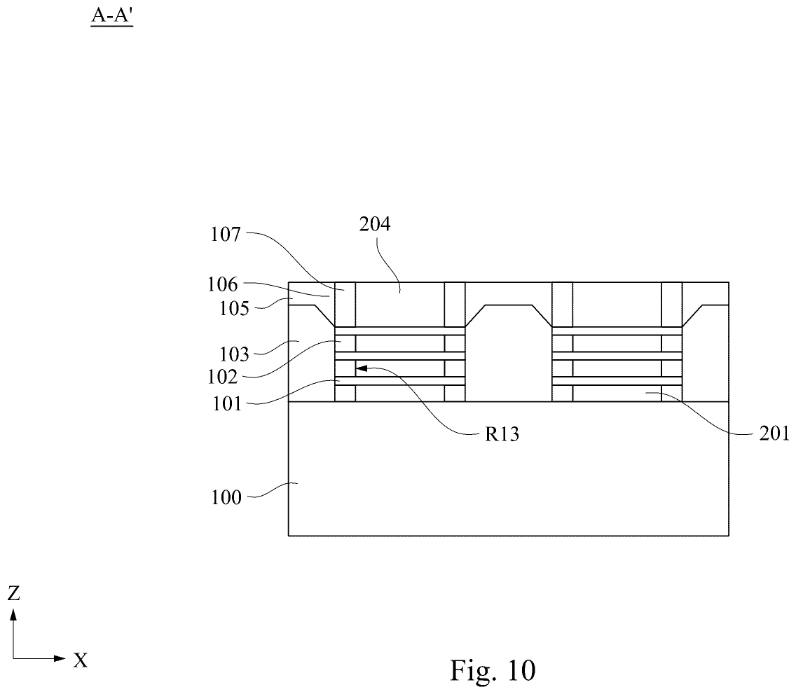

Reference is made to FIG. 10. An interlayer dielectric (ILD) layer 106 can be formed over the substrate 100. In some embodiments, the ILD layer 106 can include materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the ILD layer 106 may be deposited by a plasma-enhanced chemical vapor deposition (PECVD) process or other suitable deposition technique. In some embodiments, after formation of the ILD layer 106, the substrate 100 may be subject to a high thermal budget process to anneal the ILD layer 106. Subsequently, a planarization process (e.g., CMP) is performed to remove the excessive ILD layer 106 until the dummy gate layer 204 can be exposed. In some embodiments, the dummy gate layer 204 may also act as an etch stop layer for etching the ILD layer 106.

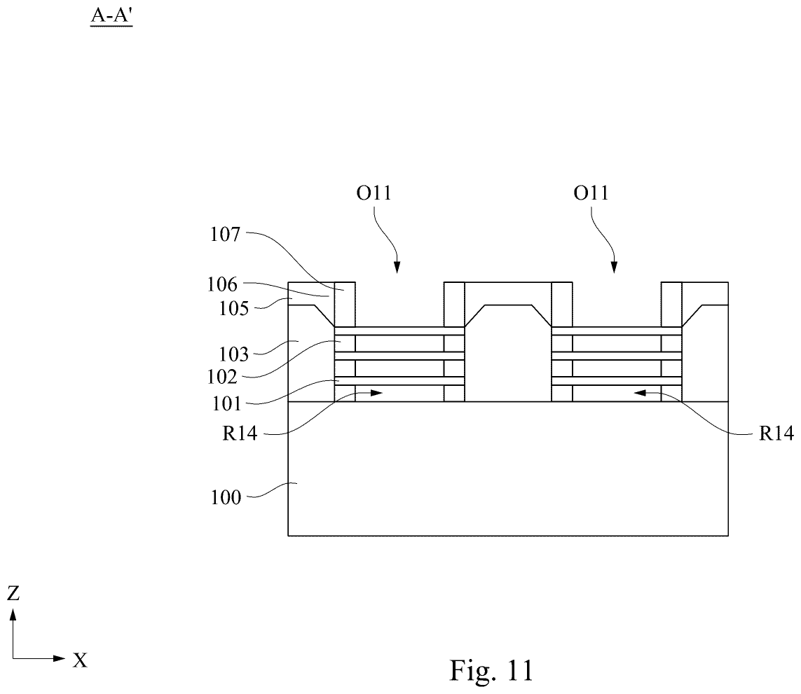

Reference is made to FIG. 11. The dummy gate layer 204 can be removed to form an opening O11. The opening O11 can expose a sidewall of the epitaxial stack, such that the channel layer 101 and the sacrificial layers 201 can be exposed from the opening O11. The etching process may include dry etching, wet etching, and/or other etching methods (e.g., reactive ion etching). In some embodiments, the opening O11 may have a rectangular profile extending along Y-direction from the top view and extend across the epitaxial stack. Subsequently, the sacrificial layers 201 can be removed in one or more etching process, so that a recess R14 can be formed to inherit the shape of the sacrificial layer 201. For example, the recess R14 can expose a bottom surface of the topmost one of the channel layers 101, and the opening O11 can expose a top surface of the topmost one of the channel layers 101. In some embodiments, the sacrificial layers 201 can be removed by an anisotropic dry etch process. For example, the etching process may include a dry etch process using reaction gas(es) that selectively etch the sacrificial layers 201 at faster rates than the substrate 100, the ILD layer 106, the channel layer 101, the inner spacer 102, and the gate spacer 107.

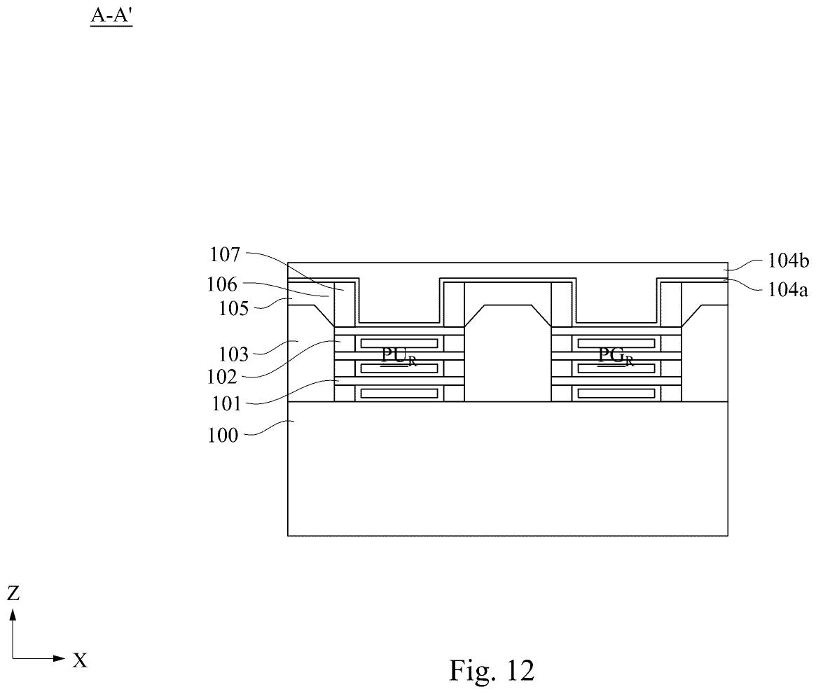

Reference is made to FIG. 12. A gate dielectric layer 104a can be conformally formed over the substrate 100 and in the opening O11 and the recesses R14. In some embodiments, the gate dielectric layer 104a may include high-k dielectric material, such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO, HZO), lanthanum oxide (LaO), zirconium oxide (ZrO), titanium oxide (TiO2), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. In some embodiments, the gate dielectric layer 104a may be deposited using any suitable method, such as CVD, physical vapor deposition (PVD), ALD, PEALD, PECVD, SACVD, FCVD, spin-on, and/or the like, or a combination thereof.

Subsequently, a gate electrode layer 104b can be deposited over the gate dielectric layer 104a. The gate electrode layer 104b may include a work function metal layer and/or a fill metal formed around the work function metal layer. The work function metal layer and/or the fill metal may include a metal, metal alloy, or metal silicide. In some embodiments, for an n-type FinFET, the work function metal layer may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TIC), aluminum carbide (AlC)), aluminides, and/or other suitable materials. On the other hand, for a p-type FinFET, the work function metal layer may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

Reference is made to FIG. 13. A planarization process (e.g., CMP) can be performed to remove the excessive gate electrode layer 104b and the gate dielectric layer 104a above the gate spacers 107. The gate spacers 107 may also act as an etch stop layer for etching the gate electrode layer 104b and the gate dielectric layer 104a. Therefore, a (metal) gate structure G1 including the gate electrode layer 104b and the gate dielectric layer 104a can be formed in the recesses R14 to surround the channel layer 101 suspended in the recesses R14. In some embodiments, the gate structure G1 may be the final gate of a GAA FET.

Therefore, the semiconductor structure can include transistors PU_{L}, PU_{R}, PG_{L}, and PG_{R}. The transistors PU_{L}, PU_{R}, PG_{L}, and PG_{R} each includes the channel layer 101, the source/drain regions 103 on opposite sides of the channel layer 101 and connected to the channel layer 101, and the gate structure G1 wrapping around the channel layer 101. In some embodiments, the transistors PU_{L}, PU_{R}, PG_{L}, and PG_{R} can be interchangeably referred to as front-side transistors. In some embodiments, the transistors PU_{L}, PU_{R}, PG_{L}, and PG_{R} may have a same conductivity type. By way of example and not limitation, the transistors PU_{L}, PU_{R}, PG_{L}, and PG_{R} may be p-type transistors. In some embodiments, the transistors PU_{L}, PU_{R}, PG_{L}, and PG_{R} may be n-type transistors.

Reference is made to FIGS. 14A and 14B. Source/drain contacts 105 can be formed over the corresponding source/drain regions 103 and penetrate through the ILD layer 106. In some embodiments, the source/drain contacts 105 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, other suitable materials, or combinations thereof.

Subsequently, an ILD layer 126 can be formed over the substrate 100. In some embodiments, the ILD layer 126 can includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the ILD layer 126 may be deposited by a plasma-enhanced chemical vapor deposition (PECVD) process or other suitable deposition technique. In some embodiments, after formation of the ILD layer 126, the substrate 100 may be subject to a high thermal budget process to anneal the ILD layer 126. Subsequently, a source/drain via 125 can be formed over the corresponding source/drain contact 105 and penetrate through the ILD layer 126. In some embodiments, the source/drain via 125 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, other suitable materials, or combinations thereof. In some embodiments, the contact 105 and/or 125 can be interchangeably referred to as a contact structure, a metal contact, a conductive contact, interconnect structure, a metal interconnect, or a conductive interconnect.

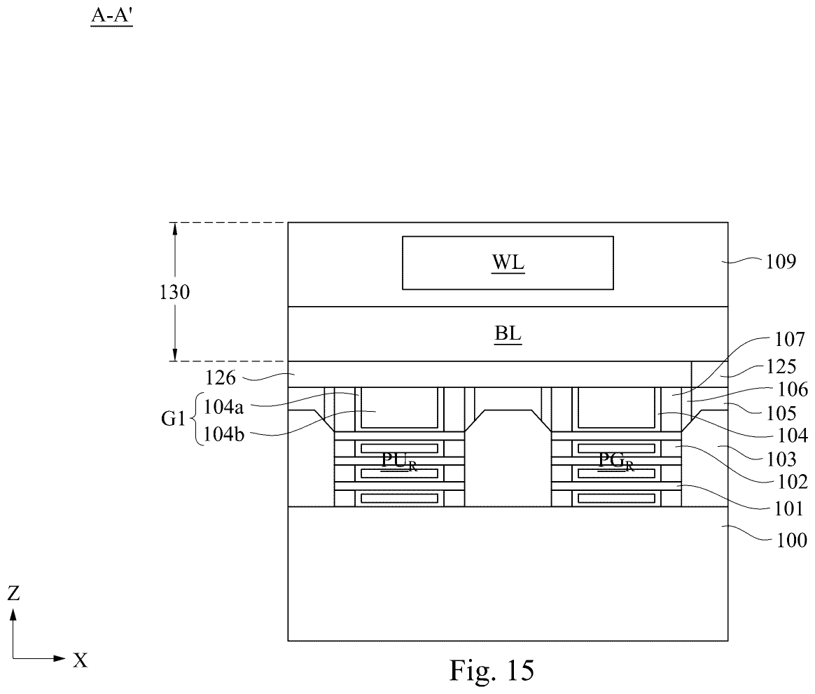

Reference is made to FIG. 15. An interconnect structure 130 can be formed over the transistors PU_{L}, PU_{R}, PG_{L}, and PG_{R}. The interconnect structure 130 may include an inter-metal dielectric 109, the bit lines BL and BLB (see FIG. 2A), and the word line WL in the inter-metal dielectric 109. In some embodiments, the bit lines BL and BLB can be formed at a same elevation. In some embodiments, the word line WL can be formed at an elevation higher than the elevation of the bit lines BL and BLB. In some embodiments, the bit line BL can be electrically connected to one of the source/drain regions 103 of the underlying transistor PG_{L} through the corresponding contact 105 (see FIG. 2A). The bit line BLB can be electrically connected to one of the source/drain regions 103 of the underlying transistor PG_{R} through the corresponding contact 105 (see FIG. 2A). The word line WL can be electrically connected to the gate structures G1 of the underlying transistors PG_{L} and PG_{R} through the corresponding contacts 105 (see FIG. 2A).

In some embodiments, the inter-metal dielectric 109 may include materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the bit lines BL and BLB and the word line WL can be made of a conductive material including, such as tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

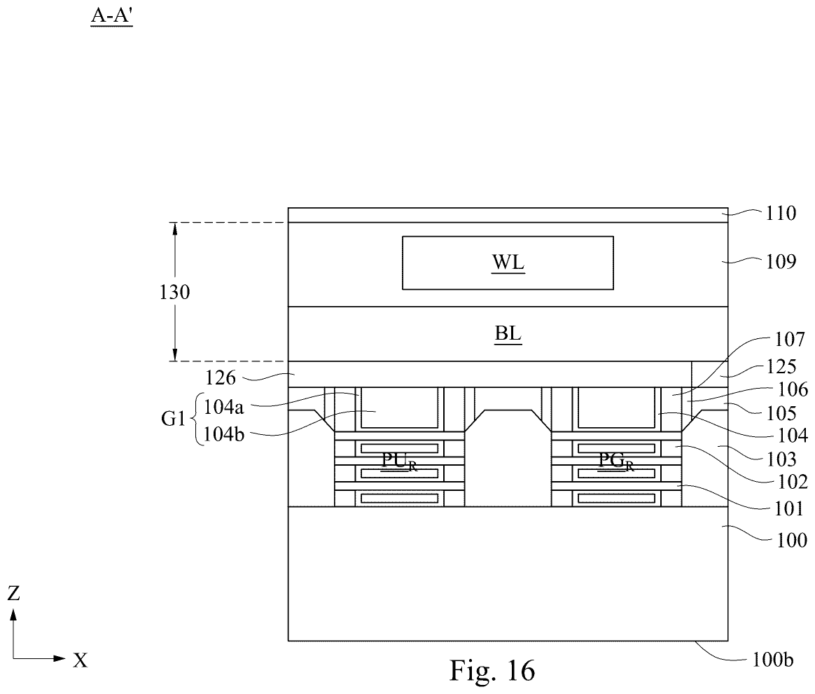

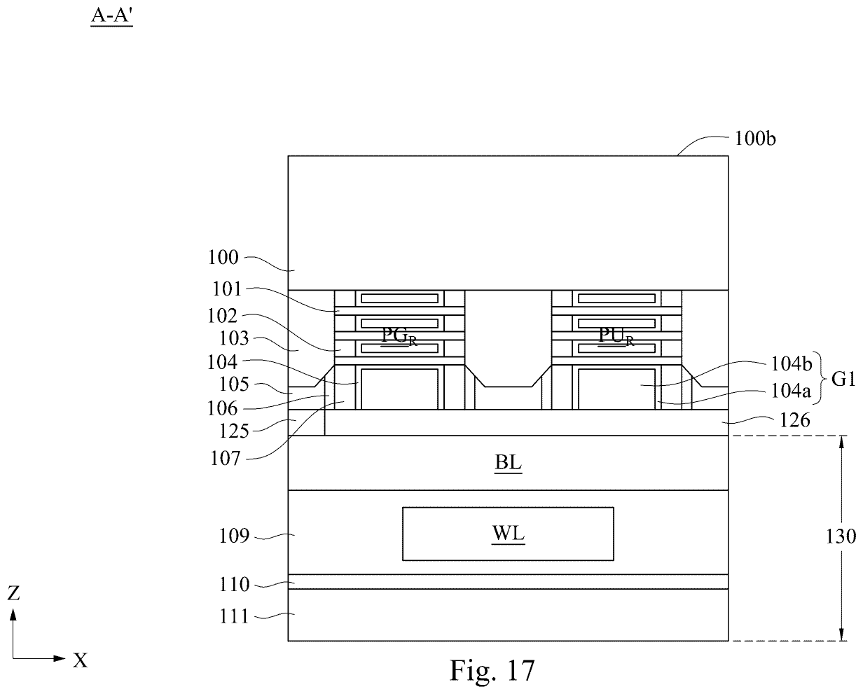

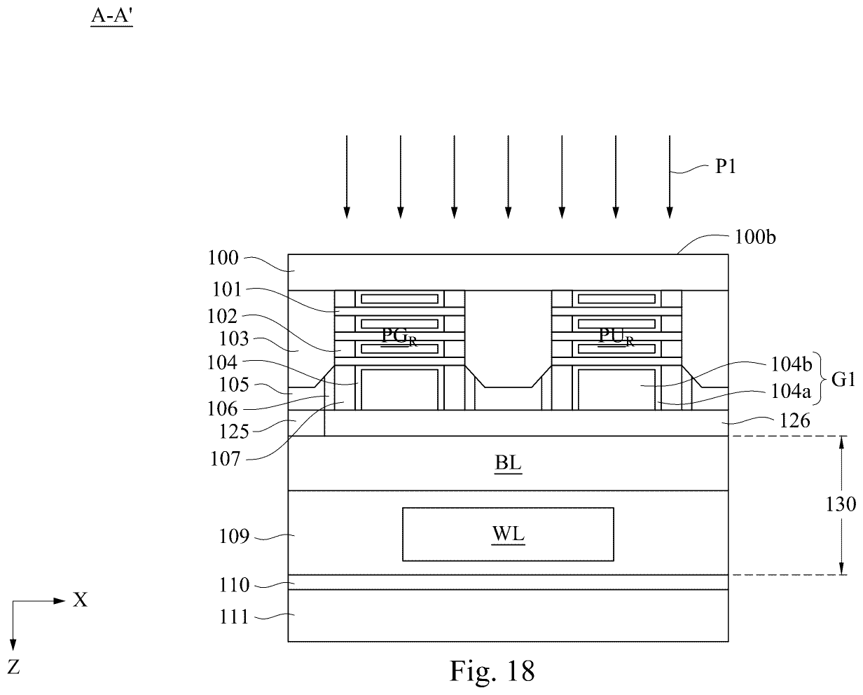

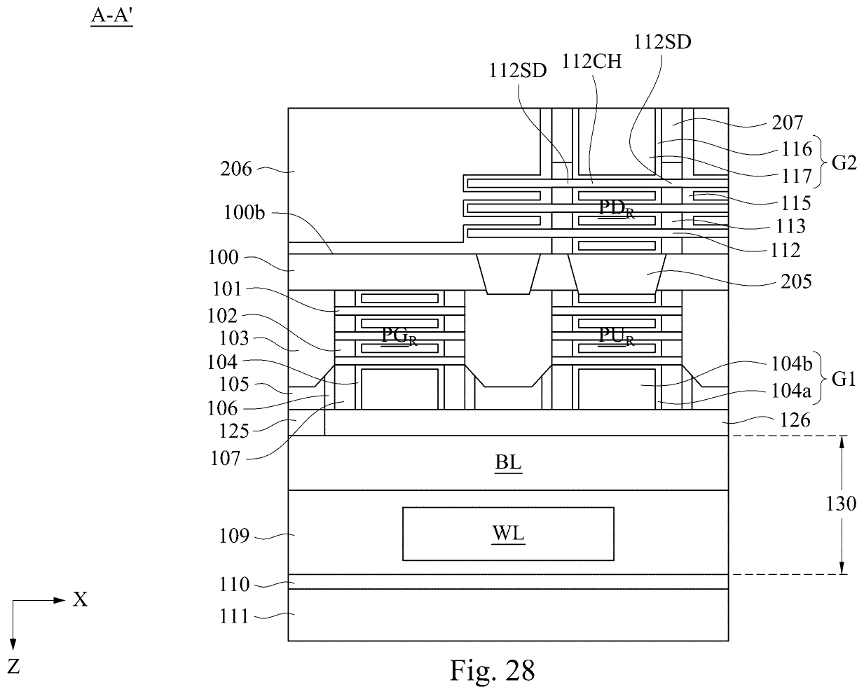

Reference is made to FIGS. 16-18. A release film 110 can be formed on a front-side surface of the interconnect structure 130 for attaching the interconnect structure 130 to a carrier wafer 111 (see FIG. 17). In some embodiments, the release film 110 may be formed of a polymer-based material (e.g., a light-to-heat-conversion (LTHC) material), which may be an epoxy-based thermal-release material. Structure shown in FIG. 16 can “flipped” upside down relative to the structure shown in FIG. 17, such that each of the transistors PU_{L}, PU_{R}, PG_{L}, and PG_{R} shown in FIG. 17 can be upside down, so that the substrate 100 can face away from the carrier wafer 111. The carrier wafer 111 can be provided to support the semiconductor structure thereon. In some embodiments, the carrier wafer 111 and the release film 110 may not be used. The carrier wafer 111, when used, may be a glass carrier, an organic carrier, or the like. As shown in FIG. 18, the back-side of the substrate 100 can be thinned down to an optimized thickness before the formation of transistors PD_{L}, PD_{R} (see FIG. 28) by a thinning process P1. In some embodiments, the back-side 100b of the substrate 100 can be thinned down by a plurality of process operations, for example, CMP, HNA, and/or TMAH etching from a back-side 100b of the substrate 100.

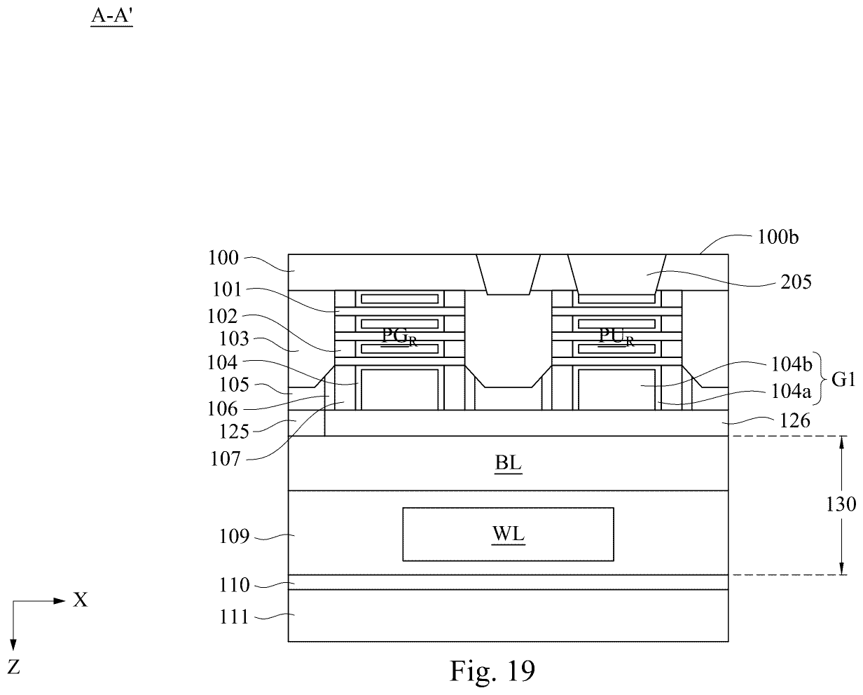

Reference is made to FIG. 19. Back-side contacts 205 can be formed through the substrate 100 from the back-side 100b of the substrate 100. The back-side contact 205 can be electrically connected to the source/drain region 103 or the gate structure G1. In some embodiments, materials of the back-side contact 205 may include Cu, Co, Ru, Pt, Al, W, Ti, TaN, TiN, Molybdenum (Mo), Ruthenium (Ru), Iridium (Ir), rhodium (Rh), or any combinations thereof.

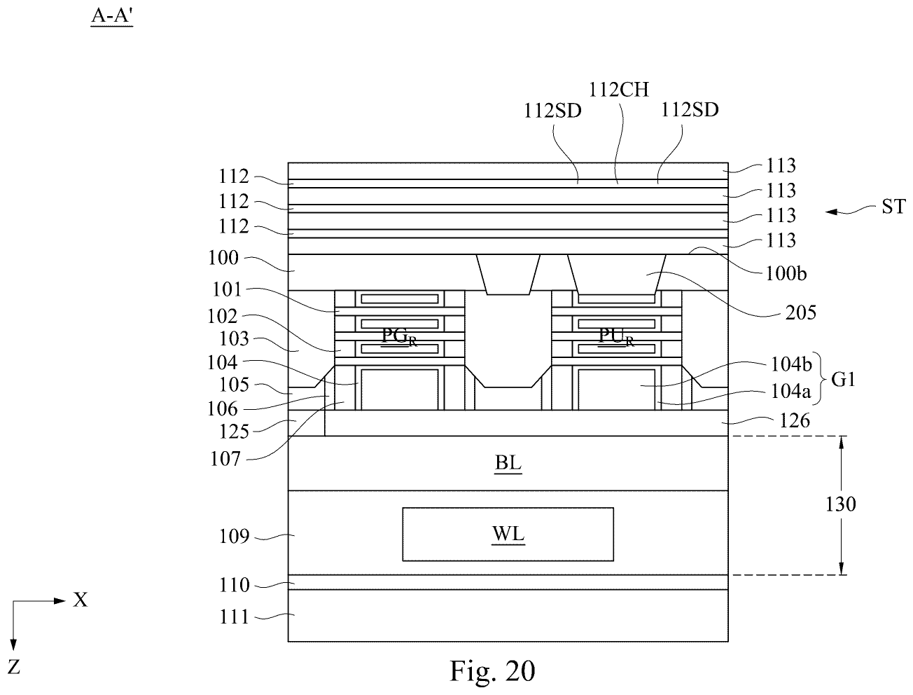

Reference is made to FIG. 20. A stack ST can be formed over the back-side 100b of the substrate 100. The stack ST can includes alternating channel material layers 112 and sacrificial layers 113. The channel material layers 112 and the sacrificial layers 113 may be formed using deposition process, such as atomic layer deposition (ALD) process, sputtering, plasma-enhanced chemical vapor deposition (PECVD) process, epitaxial growth, or other suitable deposition process. In some embodiments, portions of the sacrificial layers 113 may be removed during the following gate formation process, and portions of the sacrificial layers 113 may be removed during the following source/drain contact formation process. In some embodiments, each of the channel material layers 112 may include a channel region 112CH and source/drain regions 112SD on opposite sides of the channel region 112CH. Here, the channel region 112CH may be the portion of the channel material layer 112 that are overlapped with a gate structure (e.g., the gate structure G2 in FIG. 28). The source/drain regions 112SD may be the portions of the channel material layer 112 on opposite sides of the channel region 112CH that are not overlapped with the gate structure.

In some embodiments, the channel material layers 112 may include semiconductor material, such as oxide semiconductor material. Examples of oxide semiconductor material include indium gallium zinc oxide (InGaZnO, IGZO), InSnO, indium oxide (In₂O₃), zinc oxide (ZnO), indium gallium oxide (IGO), indium zinc oxide (InZnO, IZO). The channel material layers 112 may also include indium tin oxide (InSnO), tungsten-doped indium oxide (InWO), gallium oxide (GaOₓ), and the like. In other embodiments, the channel material layers 112 may include semiconductor material, such as silicon (Si), germanium (Ge), silicon germanium (SiGe), germanium tin (GeSn), or the like. In some embodiments, the thickness of each channel material layer 112 is in a range from about 1 nm to about 1000 nm. The channel material layers 112 may be formed using suitable deposition process, such as atomic layer deposition (ALD), sputtering, plasma enhanced chemical vapor deposition (PECVD), epitaxy deposition, or other suitable deposition process. In some embodiments, the channel material layers 112 may include amorphous structure.

The sacrificial layers 113 may include material different from the material of the channel material layers 112 to provide sufficient etching selectivity. In some embodiments where the channel material layers 112 are made of oxide semiconductor material, the sacrificial layers 113 may include dielectric material, such as silicon nitride (Si₃N₄), silicon oxide (SiOₓ), or the like. In some embodiments where the channel material layers 112 are made of oxide semiconductor material, the sacrificial layers 113 may also include conductive material, such as titanium nitride (TiN), tungsten (W), titanium (Ti), or the like. In some embodiments, the thickness of each sacrificial layer 113 is in a range from about 1 nm to about 1000 nm. The c sacrificial layers 113 may be formed using suitable deposition process, such as atomic layer deposition (ALD), sputtering, plasma enhanced chemical vapor deposition (PECVD), epitaxy deposition, or other suitable deposition process.

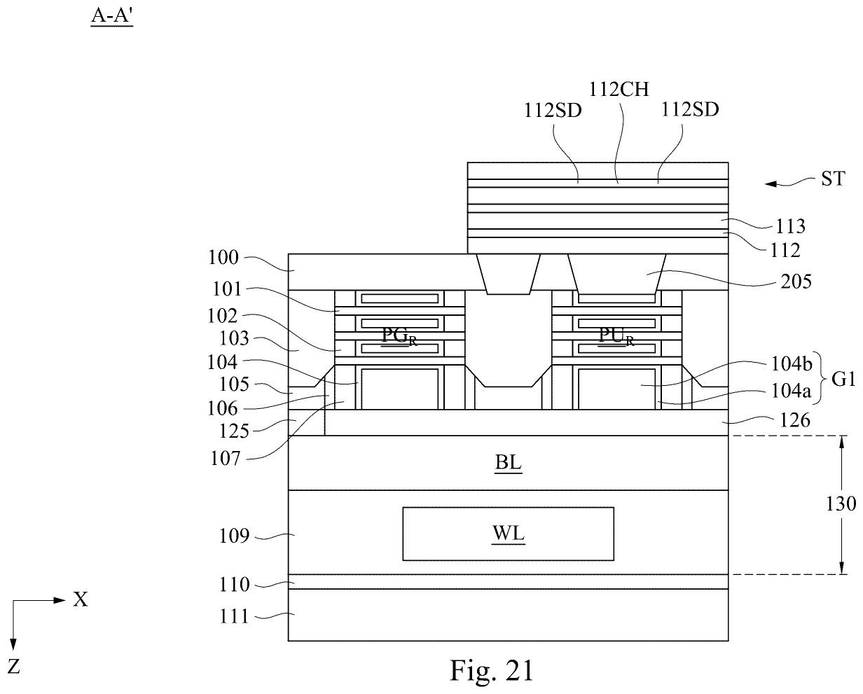

Reference is made to FIG. 21. A patterned mask (not shown) can be formed over the stack ST. The patterned mask may include openings that expose portions of the stack ST over the transistors PG_{L} and PG_{R}, in which such portions will be removed in the following step. In some embodiments, the patterned mask may include photoresist or a hard mask (e.g., silicon nitride), and may be formed by suitable photolithography process. Subsequently, portions of the stack ST that are exposed through the openings of the patterned mask can be removed. The removal process can be performed to define the width of the channel region 112CH of the channel material layers 112 along a first direction (e.g., X direction). In some embodiments, the portions of the stack ST may be removed using suitable etching process, such as wet etch, dry etch, combinations thereof, or the like. After the etching process is complete, the patterned mask MA1 may be removed.

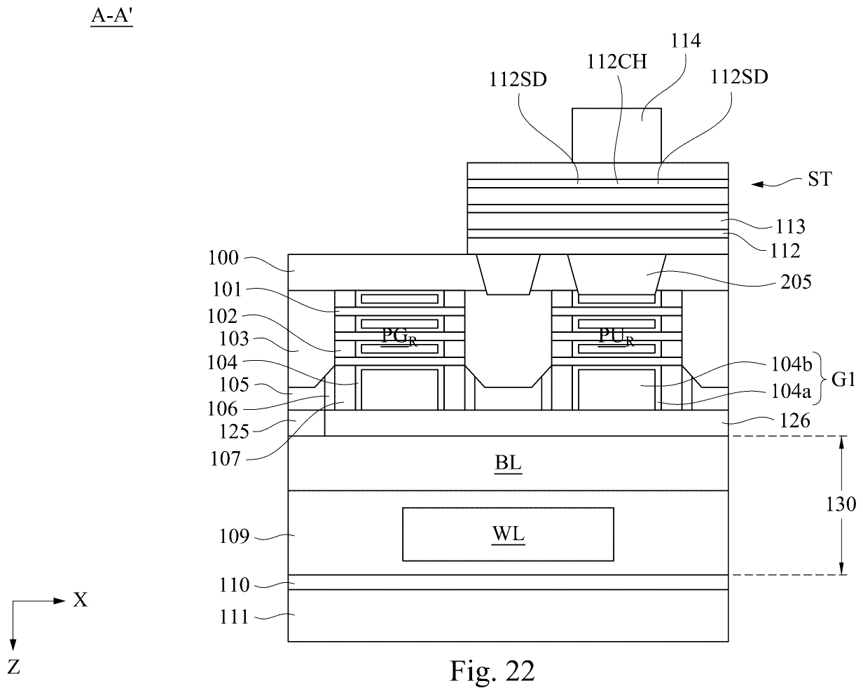

Reference is made to FIG. 22. Dummy gate layers 114 can be formed over the stack ST as shown in FIG. 21. Portions of the channel layer 101 underlying the dummy gate layers 114 may be referred to as the channel regions. Dummy gate formation operation can form the dummy gate layer 114 and the hard mask layer (not shown) over the dummy gate layer 114. The hard mask layer can be then patterned, followed by patterning the dummy gate layer 114 by using the patterned hard mask layer as an etch mask. The etch process may include a wet etch, a dry etch, and/or combinations thereof.

In some embodiments, the dummy gate layer 114 may include polycrystalline-silicon (poly-Si), poly-crystalline silicon-germanium (poly-SiGe), metallic nitrides, metallic silicides, metallic oxides, or metals. In some embodiments, the dummy gate layer 114 may include a metal-containing material such as TiN, TaN, TaC, Co, Ru, Al, combinations thereof, or multi-layers thereof. In some embodiments, the dummy gate layer 114 may be deposited by CVD, physical vapor deposition (PVD), sputter deposition, or other techniques suitable for depositing conductive materials. In some embodiments, the dummy gate layer 114 can be interchangeably referred to a dummy gate, a dummy gate pattern, a dummy gate strip, an isolation structure, or a dielectric gate.

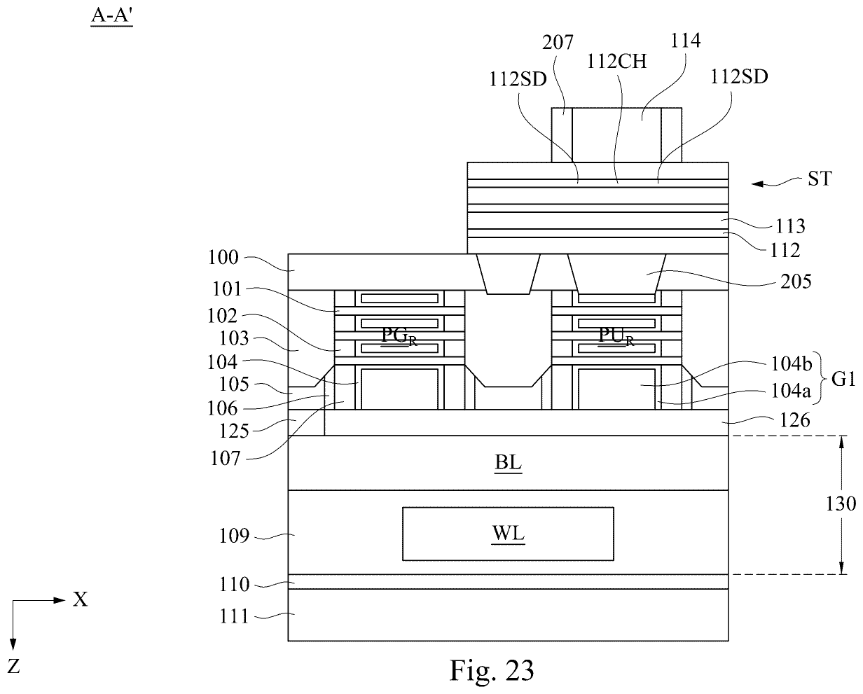

Reference is made to FIG. 23. Gate spacers 207 can be formed on sidewalls of the dummy gate layer 114. Specifically, a spacer material (not shown) can be deposited over the stack ST. The spacer material may be a conformal layer on the topmost sacrificial layer 113 and the dummy gate layer 114. The spacer material may include a dielectric material such as silicon oxide, silicon nitride, silicon carbide, silicon oxynitride, SiCN films, silicon oxycarbide, SiOCN films, and/or combinations thereof. In some embodiments, the spacer material can include multiple layers, such as a first spacer layer and a second spacer layer formed over the first spacer layer. Subsequently, an anisotropic etching process can be then performed on the deposited spacer material to expose the topmost sacrificial layer 113 and the dummy gate layer 114. Portions of the spacer material directly on the dummy gate layers 114 and on the topmost sacrificial layer 113 not covered by the dummy gate layer 114 may be completely removed by this anisotropic etching process. Portions of the spacer material on sidewalls of the dummy gate layer 114 may remain, forming gate spacers 207. The source/drain regions 112SD of the channel material layers 112 may be the portions of the channel material layers 112 vertically overlapping with the gate spacers 207.

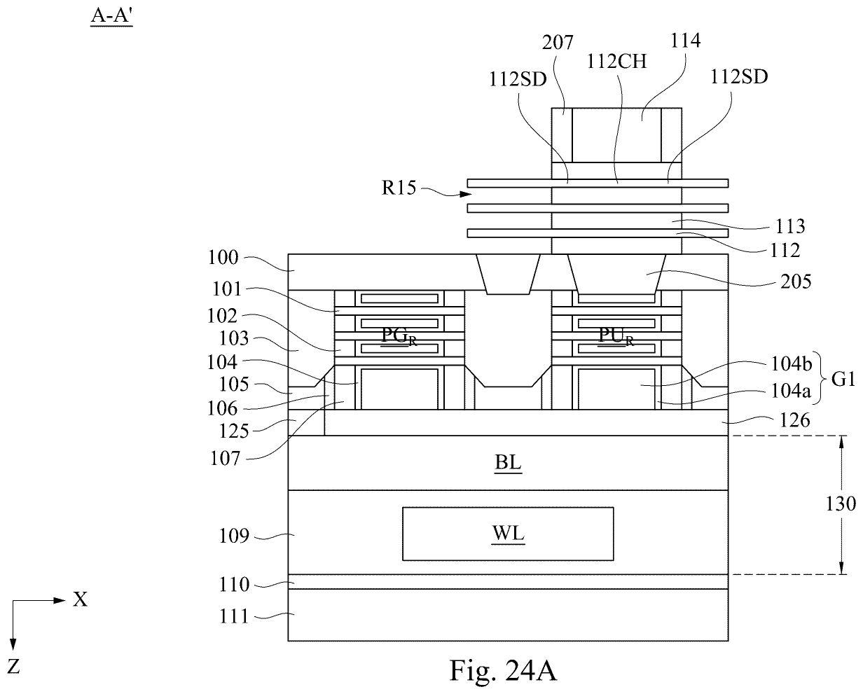

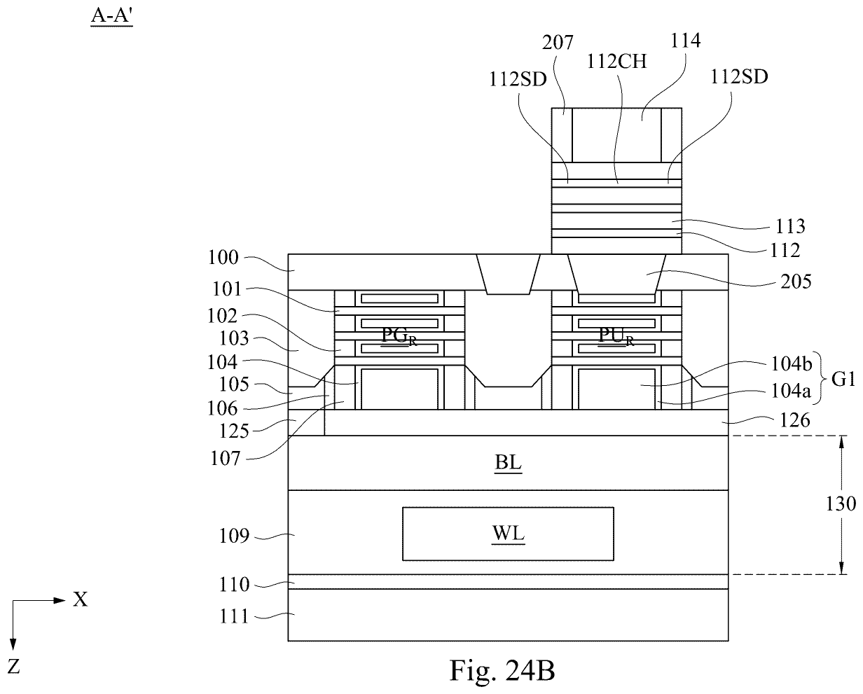

Reference is made to FIG. 24A. Exposed portions of the patterned sacrificial layers 113 that extend laterally beyond the gate spacers 207 can be etched by using, for example, an anisotropic etching process that uses the dummy gate layer 114 and the gate spacers 207 as an etch mask, resulting in recesses R15 into the channel material layers 112. On the other hand, portions of the sidewalls of the patterned sacrificial layers 113 may be recessed. Although sidewalls of the sacrificial layers 113 are illustrated as being straight, the sidewalls may be concave or convex. The sidewalls may be recessed by any acceptable etching process, such as one that is selective to the material of the sacrificial layers 113 (e.g., selectively etches the material of the sacrificial layers 113 at a faster rate than the material of the channel material layers 112).

In some embodiments, the etching of the sacrificial layers 113 may be isotropic. In some embodiments, the etching of the sacrificial layers 113 may be anisotropic. In some embodiments, the anisotropic etching may be performed by a dry chemical etch with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as HF, SF₆, CH₂F₂, CH₃F, CHF₃, or the like), chloride-based gas (e.g., Cl₂), hydrogen bromide gas (HBr), oxygen gas (O2), the like, or combinations thereof.

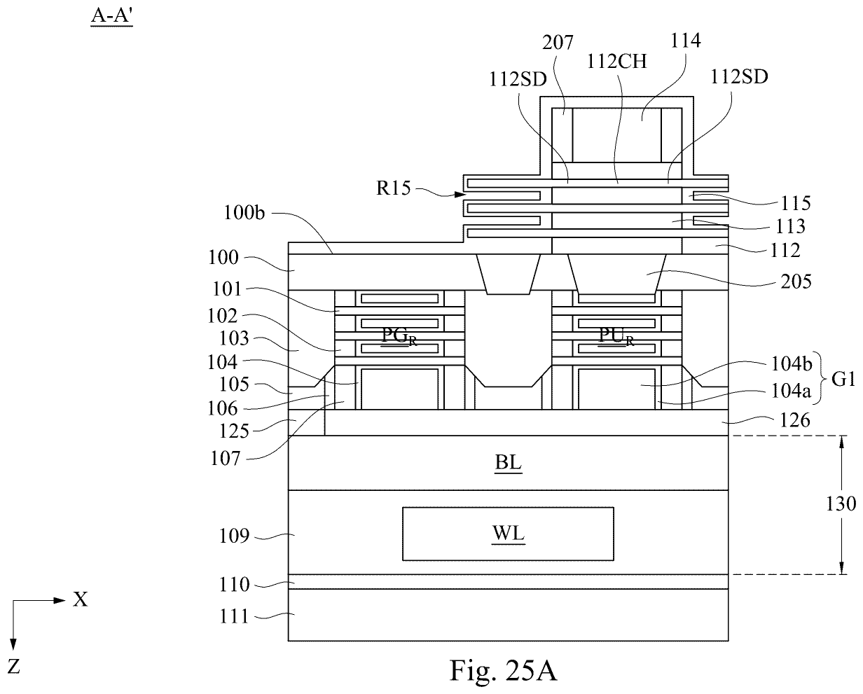

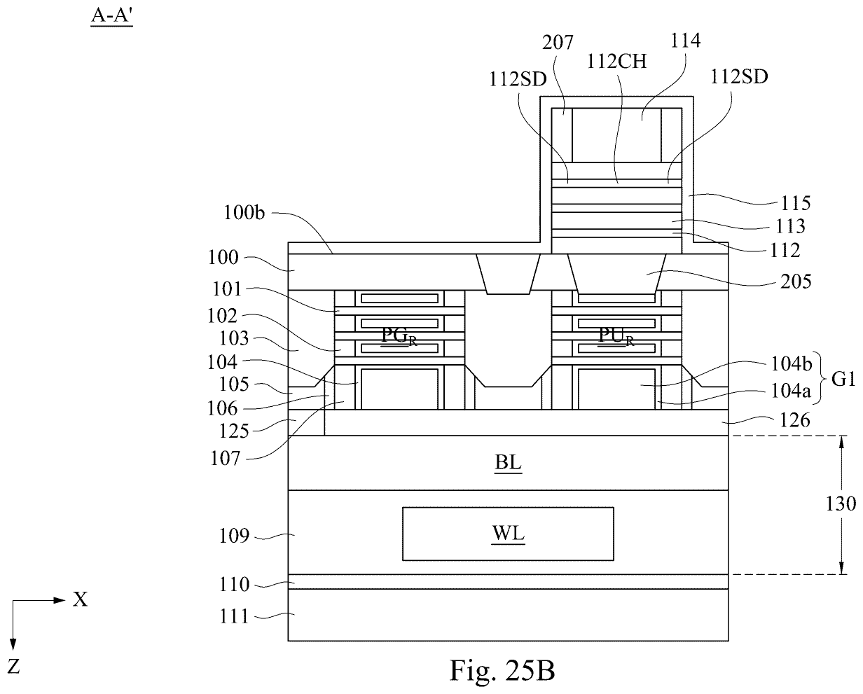

Reference is made to FIG. 25A. A conductive layer 115 can be then conformally deposited over the back-side 100b of the substrate 100. In greater detail, the conductive layer 115 can wrap around the channel material layers 112 and have portions in the recesses R15 and in contact with the sacrificial layers 113. In some embodiments, the conductive layer 115 may include titanium nitride (TiN), tungsten (W), aluminum (Al), titanium (Ti), indium gallium zinc oxide (InGaZnO, IGZO), InSnO, indium oxide (In₂O₃), zinc oxide (ZnO), indium gallium oxide (IGO), indium zinc oxide (InZnO, IZO), or the like. In some embodiments, the conductive layer 115 may be formed using a conformal deposition process, such as ALD, CVD, or the like. In some embodiments, the thickness of the conductive layer 115 is in a range from about 1 nm to about 1000 nm. In some embodiments, the conductive layer 115 can be interchangeable referred to as a source/drain metal.

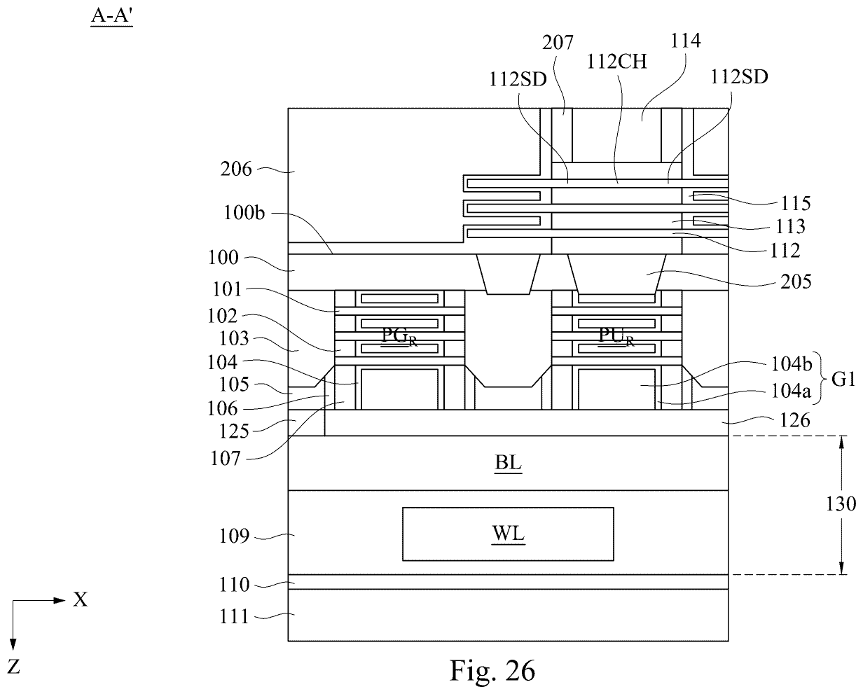

Reference is made to FIG. 26. An ILD layer 206 can be formed over the back-side 100b of the substrate 100. In some embodiments, the ILD layer 206 can include materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the ILD layer 206 may be deposited by a plasma-enhanced chemical vapor deposition (PECVD) process or other suitable deposition technique. In some embodiments, after formation of the ILD layer 206, the carrier wafer 111 may be subject to a high thermal budget process to anneal the ILD layer 206. Subsequently, a planarization process (e.g., CMP) is performed to remove the excessive ILD layer 206 until the dummy gate layer 114 can be exposed. In some embodiments, the dummy gate layer 114 may also act as an etch stop layer for etching the ILD layer 206.

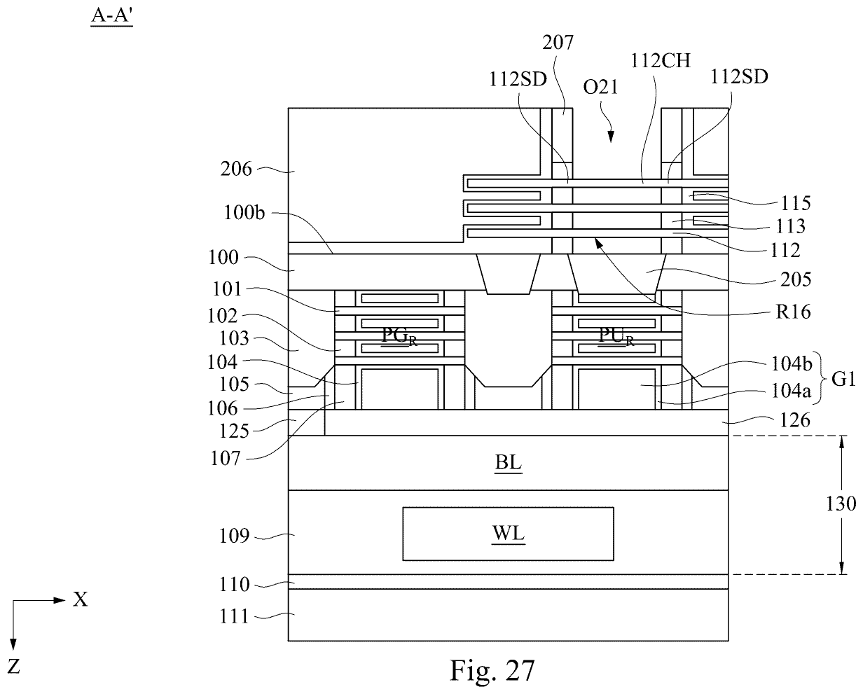

Reference is made to FIG. 27. The dummy gate layer 114 can be removed to form an opening O21. The opening O21 can expose a sidewall of the stack ST, such that the channel material layers 112 and sacrificial layers 113 can be exposed from the opening O21. The etching process may include dry etching, wet etching, and/or other etching methods (e.g., reactive ion etching). In some embodiments, the opening O21 may have a rectangular profile extending along Y-direction from the top view and extend across the stack ST.

Subsequently, exposed portions of the patterned sacrificial layers 113 that do not overlap by the gate spacers 207 can be etched by using, for example, an etching process that uses the gate spacers 207 as an etch mask, resulting in recesses R16 into the channel material layers 112. The etching process can selectively etch the material of the sacrificial layers 113 at a faster rate than the material of the channel material layers 112). In some embodiments, the etching of the sacrificial layers 113 may be isotropic. In some embodiments, the etching of the sacrificial layers 113 may be anisotropic. In some embodiments, the anisotropic etching may be performed by a dry chemical etch with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as HF, SF₆, CH₂F₂, CH₃F, CHF₃, or the like), chloride-based gas (e.g., Cl₂), hydrogen bromide gas (HBr), oxygen gas (O2), the like, or combinations thereof.

Reference is made to FIG. 28. A gate dielectric layer 116 can be deposited over the back-side 100b of the substrate 100 and wraps around each of the channel regions 112CH of the channel material layers 112. In some embodiments, the gate dielectric layer 116 is deposited using a conformal deposition process, such as ALD, CVD, or the like. In some embodiments, the thickness of the gate dielectric layer 116 is in a range from about 1 nm to about 1000 nm. The gate dielectric layer 116 may be in contact with at least four sides of each of the channel regions 112CH of the channel material layers 112. The gate dielectric layer 116 may be in contact with the sacrificial layers 113, and the barrier layer 111 may also include at least one portion having a rectangular ring shape cross-sectional top view profile.

In some embodiments, the gate dielectric layer 116 may be made of a high-k dielectric material. Examples of high-k dielectric material include aluminum oxide (Al₂O₃), hafnium oxide (HfO₂), titanium oxide (TiO₂), zirconium oxide (ZrO₂), other suitable high-k dielectric materials, and/or combinations thereof. In other embodiments, the gate dielectric layer 116 may be made of a ferroelectric (FE) material. Examples of ferroelectric material layer may be or include hafnium zirconium oxide (HfZrO), hafnium aluminum oxide (HfAlO), zirconium oxide (ZrO), hafnium oxide (HfO) doped with lanthanum (La), silicon (Si), gadolinium (Gd), aluminum (Al), or the like, undoped hafnium oxide (HfO), lead zirconate titanate (PZT), strontium bismuth tantalate (SBT), or a combination thereof.

Subsequently, a gate metal 117 can be deposited over the back-side 100b of the substrate 100 and cover the gate dielectric layer 116. The gate metal 117 may be deposited to fill the spaces between adjacent two of the channel material layers 112. Similarly, the gate metal 117 may wrap around each of the channel regions 112CH of the channel material layers 112. In some embodiments, the gate metal 117 may include titanium nitride (TiN), aluminum (Al), tungsten (W), titanium (Ti), nickel (Ni), or the like. In some embodiments, the gate metal 117 is deposited using a conformal deposition process, such as ALD, CVD, or the like. In some embodiments, the thickness of the gate metal 117 is in a range from about 1 nm to about 1000 nm. In some embodiments, the gate dielectric layer 116 and the gate metal 117 may collectively be referred to as a gate structure G2.

Subsequently, a planarization process (e.g., CMP) can be performed to remove the excessive gate metal 117 and the gate dielectric layer 116 above the gate spacers 207. The gate spacers 207 may also act as an etch stop layer for etching the gate metal 117 and the gate dielectric layer 116. Therefore, a (metal) gate structure G2 including the gate metal 117 and the gate dielectric layer 116 can be formed in the recesses R16 to surround the channel material layer 112 suspended in the recesses R16. In some embodiments, the gate structure G2 may be the final gate of a GAA FET. Therefore, the semiconductor structure can include transistors PD_{L} and PD_{R}. The transistors PD_{L} and PD_{R} each can include the channel material layer 112 and the gate structure G2 wrapping around the channel material layer 112. In some embodiments, the transistors PD_{L} and PD_{R} can be interchangeably referred to as back-side transistors. In some embodiments, the transistors PD_{L} and PD_{R} may have a different conductivity type than the transistors PU_{L}, PU_{R}, PG_{L}, and PG_{R}. By way of example and not limitation, the transistors PD_{L} and PD_{R} may be n-type transistors, and the transistors PU_{L}, PU_{R}, PG_{L}, and PG_{R} may be p-type transistors. In some embodiments, the transistors PD_{L} and PD_{R} may be p-type transistors, and the transistors PU_{L}, PU_{R}, PG_{L}, and PG_{R} may be n-type transistors.

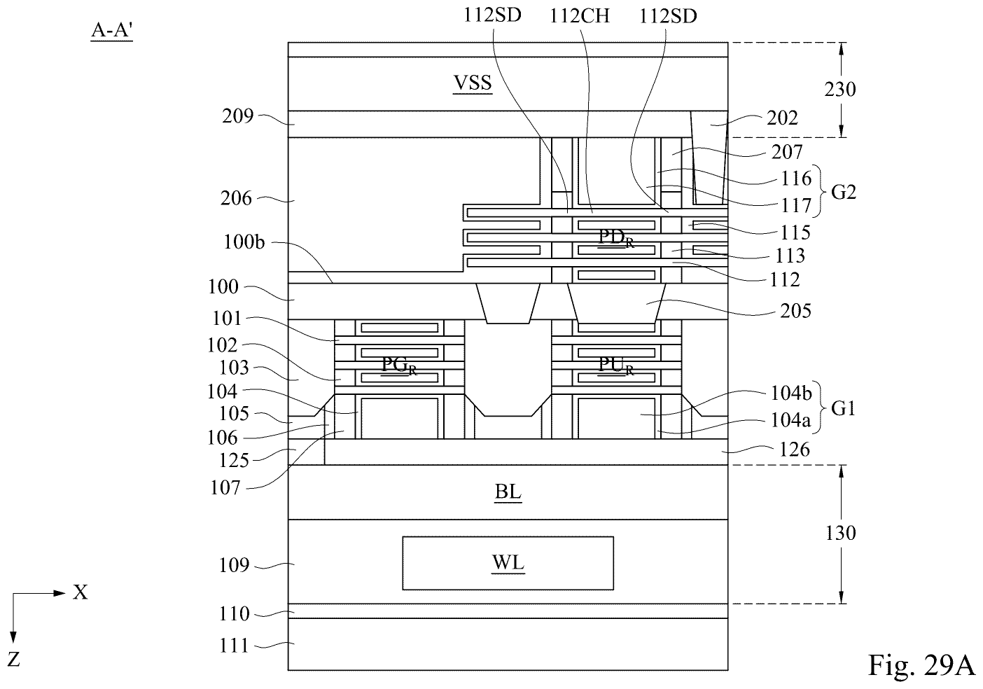

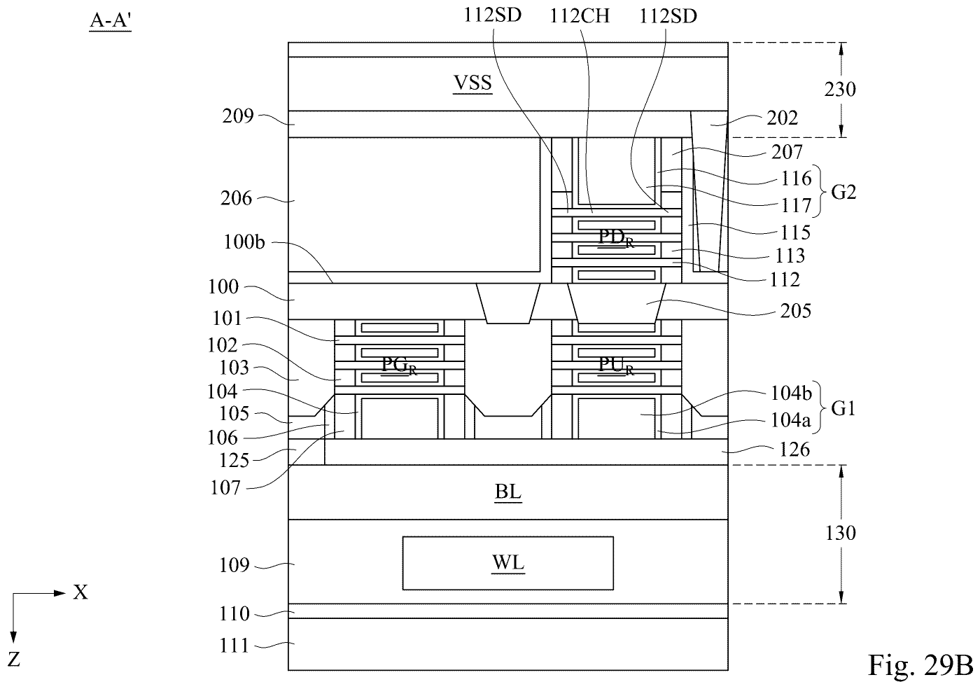

Reference is made to FIG. 29A. An interconnect structure 230 can be formed over the transistors PD_{L} and PD_{R}. The interconnect structure 230 may include an inter-metal dielectric 209, the ground line VSS and the voltage source line VDD-1/VDD-2 (see FIG. 2A) in the inter-metal dielectric 209. In some embodiments, the ground line VSS and voltage source line VDD-1/VDD-2 can be formed at a same elevation. First and second corresponding ones of the source/drain regions 112SD of the transistors PD_{L} and PD_{R} can be electrically connected to the ground line VSS through the contacts 202. As shown in FIG. 2A, first and second one of the source/drain regions 103 of the transistors PU_{L} and PU_{R} can be electrically connected to the voltage source lines VDD-1 and VDD-2 through the contacts 202.

In some embodiments, the inter-metal dielectric 209 may include materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the ground line VSS and the voltage source line VDD-1/VDD-2 can be made of tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

Reference is made to FIGS. 24B, 25B, and 29B. FIGS. 24B, 25B, and 29B illustrate schematic views of intermediate stages in the formation of a semiconductor structure in accordance with some embodiments of the present disclosure. While FIGS. 24B, 25B, and 29B illustrate embodiments of a semiconductor structure with a different structure configuration than the semiconductor structure shown in FIGS. 4A-24A, 25A, and 26-29A, the present disclosure may repeat reference numerals and/or letters in the various examples. This repetition is for the purpose of simplicity and clarity and does not in itself dictate a relationship between the various embodiments and/or configurations discussed.

Specifically, the distinction between the semiconductor structure shown in FIGS. 24B, 25B, and 29B and the semiconductor structure shown in FIGS. 4A-24A, 25A, and 26-29A may lie in the configuration and treatment of the channel material layers 112. In FIGS. 24B, 25B, and 29B, the channel material layer 112 does not extend or protrude beyond the opposite sidewalls of the sacrificial layer 113. Specifically, FIG. 24B illustrates that during the anisotropic etching process, which utilizes the dummy gate layer 114 and gate spacers 207 as an etch mask, both the channel material layers 112 and the sacrificial layers 113 can be tailored to ensure that their end surfaces and the outermost sidewalls of the gate spacers 107 align (or are coterminous), thus providing a more streamlined and uniform structure. Although illustrated as having straight sidewalls, the channel material layers 112 shown in FIGS. 24B, 25B, and 29B can exhibit varied shapes, such as concave or convex. As shown in FIG. 25B, the conductive layer 115 can be conformally deposited over the back-side 100b of the substrate for ensuring proper electrical connectivity and functionality in the semiconductor device. As shown in FIG. 29B, the subsequent formation of the interconnect structure 230 can be formed for the integration and connection of the semiconductor components within the overall device architecture.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides an improved SRAM bit-cell configuration, employing back-side oxide semiconductor pull-down transistors to enhance the performance, power efficiency, and area utilization of high-density 6T SRAM bit-cells. By relocating the pull-down transistors to the back-side of the semiconductor structure, the configuration can achieve improved electrical characteristics. Furthermore, the 6T SRAM bit-cell with two back-side oxide semiconductor pull-down transistors, coupled with front-side p-type metal-oxide-semiconductor (MOS) pass-gate and pull-up transistors can not only optimize the electrical paths and reduces parasitic effects but also shrink the cell area, enhancing overall chip density.

In some embodiments, a method includes forming a front-side pass-gate transistor over a front-side of a substrate, wherein the front-side pass-gate transistor is comprised in a memory bit-cell, and is of a first conductivity type; forming a back-side pull-down transistor over a back-side of the substrate, wherein the back-side pull-down transistor is comprised in the memory bit-cell, and is of a second conductivity type opposite to the first conductivity type, and the back-side pull-down transistor is an oxide semiconductor transistor. In some embodiments, the front-side pass-gate transistor is a p-type transistor, and the back-side pull-down transistor is an n-type transistor. In some embodiments, the method further includes forming a front-side pull-up transistor over the front-side of the substrate, wherein the front-side pull-up transistor is comprised in the memory bit-cell, and is at a same level height as the front-side pass-gate transistor. In some embodiments, the front-side pull-up transistor is of the first conductivity type. In some embodiments, the memory bit-cell has a footprint on the substrate, and the footprint encompasses up to four transistors located on a same level. In some embodiments, the method further includes forming a bit line and a bit line bar over the front-side pass-gate transistor; forming a word line over the bit line and the bit line bar. In some embodiments, the back-side pull-down transistor comprises an active layer being made of an oxide semiconductive material. In some embodiments, the oxide semiconductive material comprises InGaZnO, InSnO, In₂O₃, InZnO, or combinations thereof. In some embodiments, the back-side pull-down transistor comprises a source/drain metal over the active layer, and the source/drain metal comprises TiN, W, InGaZnO, InSnO, In₂O₃, InZnO, or combinations thereof. In some embodiments, the method further includes after forming the back-side pull-down transistor, forming a backside power delivery network over the back-side of the substrate.

In some embodiments, a method includes forming a semiconductive nanostructure over a front-side of a substrate, wherein the semiconductive nanostructure is comprised in a static random access memory (SRAM) cell; forming epitaxial structures on opposite sides of the semiconductive nanostructure; forming a first gate structure wrapping around the semiconductive nanostructure; forming an oxide semiconductive active layer over a back-side of the substrate, wherein the oxide semiconductive active layer is comprised in the SRAM cell; forming source/drain metals on opposite sides of the oxide semiconductive active layer; forming a second gate structure wrapping around the oxide semiconductive active layer. In some embodiments, the semiconductive nanostructure, the epitaxial structures, and the first gate structure collectively form a pass-gate transistor or a pull-up transistor of the SRAM cell. In some embodiments, the oxide semiconductive active layer, the source/drain metals, and the second gate structure collectively form a pull-down transistor. In some embodiments, forming the oxide semiconductive active layer, forming the source/drain metals, and forming the second gate structure are performed after forming the semiconductive nanostructure, forming the epitaxial structures, and forming the first gate structure. In some embodiments, the oxide semiconductive active layer is made of an amorphous material. In some embodiments, forming the oxide semiconductive active layer is performing under a temperature lower than about 400 C.

In some embodiments, the semiconductor structure includes a plurality of back-side power lines, a memory cell, and a signal line. The back-side power lines are over a substrate. The memory cell is over the back-side power lines. The memory cell includes first and second pull-down transistors at a first level height, first and second pull-up transistors at a second level height different than the first level height, and first and second pass-gate transistors at the second level height. The memory cell has a footprint on the substrate, and the footprint encompasses up to four transistors located on a same level. The signal line is over the memory cell. In some embodiments, the first and second pass-gate transistors are oxide semiconductor transistors. In some embodiments, the first and second pass-gate transistors are of a same conductivity type as the first and second pull-up transistors. In some embodiments, the first and second pull-down transistors are of a different conductivity type than the first and second pass-gate transistors.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein.

Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a front-side pass-gate transistor over a front-side of a substrate, wherein the front-side pass-gate transistor is comprised in a memory bit-cell, and is of a first conductivity type; and
forming a back-side pull-down transistor over a back-side of the substrate, wherein the back-side pull-down transistor is comprised in the memory bit-cell, and is of a second conductivity type opposite to the first conductivity type, and the back-side pull-down transistor is an oxide semiconductor transistor.

2. The method of claim 1, wherein the front-side pass-gate transistor is a p-type transistor, and the back-side pull-down transistor is an n-type transistor.

3. The method of claim 1, further comprising:
forming a front-side pull-up transistor over the front-side of the substrate, wherein the front-side pull-up transistor is comprised in the memory bit-cell, and is at a same level height as the front-side pass-gate transistor.

4. The method of claim 3, wherein the front-side pull-up transistor is of the first conductivity type.

5. The method of claim 1, wherein the memory bit-cell has a footprint on the substrate, and the footprint encompasses up to four transistors located on a same level.

6. The method of claim 1, further comprising:
forming a bit line and a bit line bar over the front-side pass-gate transistor; and
forming a word line over the bit line and the bit line bar.

7. The method of claim 1, wherein the back-side pull-down transistor comprises an active layer being made of an oxide semiconductive material.

8. The method of claim 7, wherein the oxide semiconductive material comprises InGaZnO, InSnO, In₂O₃, InZnO, or combinations thereof.

9. The method of claim 7, wherein the back-side pull-down transistor comprises a source/drain metal over the active layer, and the source/drain metal comprises TiN, W, InGaZnO, InSnO, In₂O₃, InZnO, or combinations thereof.

10. The method of claim 1, further comprising:
after forming the back-side pull-down transistor, forming a backside power delivery network over the back-side of the substrate.

11. A method, comprising:
forming a semiconductive nanostructure over a front-side of a substrate, wherein the semiconductive nanostructure is comprised in a static random access memory (SRAM) cell;
forming epitaxial structures on opposite sides of the semiconductive nanostructure;
forming a first gate structure wrapping around the semiconductive nanostructure;
forming an oxide semiconductive active layer over a back-side of the substrate, wherein the oxide semiconductive active layer is comprised in the SRAM cell;
forming source/drain metals on opposite sides of the oxide semiconductive active layer; and
forming a second gate structure wrapping around the oxide semiconductive active layer.

12. The method of claim 11, wherein the semiconductive nanostructure, the epitaxial structures, and the first gate structure collectively form a pass-gate transistor or a pull-up transistor of the SRAM cell.

13. The method of claim 11, wherein the oxide semiconductive active layer, the source/drain metals, and the second gate structure collectively form a pull-down transistor.

14. The method of claim 11, wherein forming the oxide semiconductive active layer, forming the source/drain metals, and forming the second gate structure are performed after forming the semiconductive nanostructure, forming the epitaxial structures, and forming the first gate structure.

15. The method of claim 11, wherein the oxide semiconductive active layer is made of an amorphous material.

16. The method of claim 11, wherein forming the oxide semiconductive active layer is performing under a temperature lower than about 400° C.

17. A semiconductor structure, comprising:
a plurality of back-side power lines over a substrate;
a memory cell over the back-side power lines, the memory cell comprising first and second pull-down transistors at a first level height, first and second pull-up transistors at a second level height different than the first level height, and first and second pass-gate transistors at the second level height, wherein the memory cell has a footprint on the substrate, and the footprint encompasses up to four transistors located on a same level; and
a signal line over the memory cell.

18. The semiconductor structure of claim 17, wherein the first and second pass-gate transistors are oxide semiconductor transistors.

19. The semiconductor structure of claim 17, wherein the first and second pass-gate transistors are of a same conductivity type as the first and second pull-up transistors.

20. The semiconductor structure of claim 17, wherein the first and second pull-down transistors are of a different conductivity type than the first and second pass-gate transistors.
